(19) United States
(12) Patent Application Publication
(10) Pub. No.: US 2026/0068693 A1
(43) Pub. Date: Mar. 5, 2026

(54) POWER SEMICONDUCTOR DEVICE PACKAGE

(71) Applicant: Wolfspeed, Inc., Durham, NC (US)

(72) Inventors: Adil Salman, Morrisville, NC (US); Geza Dezsi, Durham, NC (US); Adam Benjamin Barkley, Chapel Hill, NC (US)

(21) Appl. No.: 18/816,797

(22) Filed: Aug. 27, 2024

(51) Int. Cl. H01L 23/495; H01L 21/56; H01L 23/00; H01L 23/538; H01L 25/07

(52) U.S. Cl. CPC H01L 23/49537

(57) ABSTRACT

Power semiconductor device packages and method for manufacturing the same are provided. In one example, a power semiconductor device package may include a housing that defines a housing plane, a first semiconductor die on a first submount, a second semiconductor die on a second submount, and a creepage extension structure in the housing. The first submount may be electrically isolated from the second submount. In one example, the power semiconductor device package may further include a first plurality of electrical leads extending from the housing and a second plurality of electrical leads extending from the housing. In one example, the second plurality of electrical leads may be rotated 180-degrees about the housing plane relative to the first plurality of electrical leads.

### FIELD

The present disclosure relates generally to semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices. Example semiconductor devices may be power modules, which may include one or more power devices and other circuit components and can be used, for instance, to dynamically switch large amounts of power through various components, such as motors, inverters, generators, and the like. These semiconductor devices may be fabricated from wide bandgap semiconductor materials, such as silicon carbide (“SiC”) and/or Group III nitride-based semiconductor materials.

### SUMMARY

Aspects and advantages of embodiments of the present disclosure will be set forth in part in the following description, or can be learned from the description, or can be learned through practice of the embodiments.

One example aspect of the present disclosure is directed to a power semiconductor device package. The power semiconductor device package includes a housing, a first semiconductor die on a first submount, a second semiconductor die on a second submount, and a creepage extension structure in the housing. At least a portion of the creepage extension structure is between the first semiconductor die and the second semiconductor die.

Another example aspect of the present disclosure is directed to a power semiconductor device package. The power semiconductor device package includes a housing, a first semiconductor die on a first submount, and a second semiconductor die on a second submount that is electrically isolated from the first submount.

Another example aspect of the present disclosure is directed to a method. The method includes providing a first submount and a second submount. The method further includes coupling a first semiconductor die to the first submount. The method further includes coupling a second semiconductor die to the second submount. The method further includes providing an encapsulating material around the first submount and the second submount, the encapsulating material forming a housing. The method further includes providing a creepage extension structure in the housing between the first semiconductor die and the second semiconductor die.

Another example aspect of the present disclosure is directed to a power semiconductor device package. The power semiconductor device package includes a housing, a first semiconductor die on a first submount, a second semiconductor die on a second submount, and a creepage extension structure in the housing between the first semiconductor die and the second semiconductor die. The creepage extension structure includes a first creepage portion between the first semiconductor die and the second semiconductor die, a second creepage portion perpendicular to the first creepage portion and extending laterally from the first creepage portion towards the first semiconductor die, and a third creepage portion perpendicular to the first creepage portion and extending laterally from the first creepage portion towards the second semiconductor die.

Another example aspect of the present disclosure is directed to a power semiconductor device package. The power semiconductor device package includes a housing having a major surface. The housing defines a housing plane. The power semiconductor device package further includes a first semiconductor die on a first submount. The first semiconductor die defines a first portion of the housing. The power semiconductor device package further includes a first plurality of electrical leads extending from the first portion of the housing. The power semiconductor device package further includes a second semiconductor die on a second submount. The second semiconductor die defines a second portion of the housing that is different from the first portion. The power semiconductor device package further includes a second plurality of electrical leads extending from the second portion of the housing. The second plurality of electrical leads are rotated 180-degrees about the housing plane relative to the first plurality of electrical leads.

Another example aspect of the present disclosure is directed to a power semiconductor device package. The power semiconductor device package includes a housing, a first semiconductor die on a first submount, a first plurality of electrical leads coupled to the first semiconductor die and extending from the housing, a second semiconductor die on a second submount, and a second plurality of electrical leads coupled to the second semiconductor die and extending from the housing. The first plurality of electrical leads includes a first lead coupled to a source contact of the first semiconductor die, a second lead coupled to a gate contact of the first semiconductor die, and a third lead coupled to a drain contact of the first semiconductor die. The second plurality of electrical leads includes a first lead coupled to a source contact of the second semiconductor die, a second lead coupled to a gate contact of the second semiconductor die, and a third lead coupled to a drain contact of the second semiconductor die. The first lead and the second lead of the first plurality of electrical leads extend from an opposing side of the housing relative to the first lead and the second lead of the second plurality of electrical leads.

Another example aspect of the present disclosure is directed to a power semiconductor device package. The power semiconductor device package includes a housing, a first semiconductor die on a first submount, and a second semiconductor die on a second submount. The first semiconductor die and the second semiconductor die are arranged within the housing in a half-bridge arrangement.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a top plan view of an example power semiconductor device package according to example embodiments of the present disclosure;

FIG. 2 depicts a bottom plan view of the example power semiconductor device package of FIG. 1 according to example embodiments of the present disclosure;

FIG. 3 depicts a side plan view of the example power semiconductor device package of FIG. 1 according to example embodiments of the present disclosure;

FIG. 4 depicts a side plan view of the example power semiconductor device package of FIG. 1 according to example embodiments of the present disclosure;

FIG. 5 depicts a top wireframe view of the example power semiconductor device package of FIG. 1 according to example embodiments of the present disclosure;

FIG. 6 depicts a perspective wireframe of the example power semiconductor device package of FIG. 5 according to example embodiments of the present disclosure;

FIG. 7 depicts a top wireframe view of the example power semiconductor device package of FIG. 1 according to example embodiments of the present disclosure;

FIG. 8 depicts a side wireframe view of the example power semiconductor device package of FIG. 7 according to example embodiments of the present disclosure;

FIG. 9 depicts a bottom plan view of the example power semiconductor device package of FIG. 1 according to example embodiments of the present disclosure;

FIG. 10 depicts a top plan view of an example power semiconductor device package according to example embodiments of the present disclosure;

FIG. 11 depicts a top perspective view of the example power semiconductor device package of FIG. 10 according to example embodiments of the present disclosure;

FIG. 12 depicts a cross-sectional side view of the example power semiconductor device package of FIG. 10 according to example embodiments of the present disclosure;

FIG. 13 depicts a bottom perspective view of the example power semiconductor device package of FIG. 10 according to example embodiments of the present disclosure;

FIG. 14 depicts a bottom perspective view of the example power semiconductor device package of FIG. 10 according to example embodiments of the present disclosure;

FIG. 15 depicts a bottom perspective view of the example power semiconductor device package of FIG. 10 according to example embodiments of the present disclosure;

FIG. 16A-16G depict example creepage extension structures of a power semiconductor device package according to example embodiments of the present disclosure;

FIG. 17 depicts a top plan view of an example power semiconductor device package according to example embodiments of the present disclosure;

FIG. 18 depicts a bottom plan view of the example power semiconductor device package of FIG. 17 according to example embodiments of the present disclosure;

FIG. 19 depicts a cross-sectional side view of the example power semiconductor device package of FIG. 17 according to example embodiments of the present disclosure;

FIG. 20 depicts a top plan view of an example power semiconductor device package according to example embodiments of the present disclosure;

FIG. 21 depicts a bottom plan view of the example power semiconductor device package of FIG. 20 according to example embodiments of the present disclosure;

FIG. 22 depicts a bottom wireframe view of the example power semiconductor device package of FIG. 20 according to example embodiments of the present disclosure;

FIG. 23 depicts a top wireframe view of an example power semiconductor device package according to example embodiments of the present disclosure;

FIG. 24 depicts a top wireframe view of an example power semiconductor device package according to example embodiments of the present disclosure;

FIG. 25A depicts a top perspective view of a portion of an example power semiconductor device package according to example embodiments of the present disclosure;

FIG. 25B depicts a top perspective view of a portion of an example power semiconductor device package according to example embodiments of the present disclosure;

FIG. 26A-26B depict example electrical leads of a power semiconductor device package according to example embodiments of the present disclosure;

FIG. 27 depicts a flow chart diagram of an example method according to example embodiments of the present disclosure; and

FIG. 28 depicts a flow chart diagram of an example method according to example embodiments of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor device packages (e.g., discrete semiconductor device packages and power modules) have been developed that include a semiconductor die. In some examples, such semiconductor die include one or more semiconductor devices, such as a metal-oxide-semiconductor field-effect transistor (MOSFET), a Schottky diode, and/or a high electron mobility transistor (HEMT) device. Semiconductor device packages with MOSFETs may be employed in a variety of applications to enable higher switching frequencies along with reduced associated losses, higher blocking voltages, and improved avalanche capabilities. Example applications may include high performance industrial power supplies, server/telecom power, electric vehicle charging systems, energy storage systems, uninterruptible power supplies, high-voltage DC/DC converters, electric vehicles, and battery management systems. Semiconductor device packages with Schottky diodes and/or HEMT devices may be employed in many of the same high-performance power applications described above for MOSFETs, sometimes in systems that also include discrete power packages of MOSFETs.

Example aspects of the present disclosure are directed to power semiconductor device packages for use in semiconductor applications and other electronic applications. It should be understood that the terms “semiconductor device package,” “semiconductor package,” “power semiconductor device package,” and/or “power semiconductor package” may be used interchangeably. In some examples, semiconductor device packages may include one or more semiconductor die. The one or more semiconductor die may include a wide bandgap semiconductor material. A wide bandgap semiconductor has a band gap greater than about 1.40 eV, such as silicon carbide and/or a Group-III nitride (e.g., gallium nitride).

In some examples, the one or more semiconductor die may include one or more semiconductor devices, such as transistors, diodes, and/or thyristors. For instance, in some examples, the one or more semiconductor die may include a MOSFET, such as a silicon carbide-based MOSFET. Additionally and/or alternatively, in some examples, the one or more semiconductor die may include a Schottky diode, such as a silicon carbide-based Schottky diode. Additionally and/or alternatively, in some examples, the one or more semiconductor die may include a HEMT device, such as a Group-III nitride-based HEMT device.

It should be understood that aspects of the present disclosure are discussed with reference to silicon carbide-based MOSFET devices for purposes of illustration and discussion. Those having ordinary skill in the art, using the disclosures provided herein, will understand that the power semiconductor package of the present disclosure may include other power semiconductor devices without deviating from the scope of the present disclosure, such as diodes (e.g., Schottky diodes, PiN diodes, etc.), insulated gate bipolar transistors, HEMTs, or other devices.

In some power semiconductor device packages, the one or more semiconductor die may be attached to a submount, such as a lead frame and/or a power substrate (e.g., direct bonded copper (DBC) substrate, active metal brazed (AMB) substrate, etc.), by a die-attach material between the one or more semiconductor die and the submount. For instance, in some examples, a die-attach material may be deposited on the submount, and the semiconductor die (or other component) may be placed on the die-attach material, and the die-attach material may be subjected to bonding or a bonding process (e.g., sintering) to secure the semiconductor die (or other component) to the die-attach material. Various types of die-attach material may be used to bond the one or more semiconductor die to the submount such as, for instance, metal sintering die-attach (e.g., silver (Ag) or copper (Cu)) and conductive adhesive die-attach. Additionally and/or alternatively, in some examples, the power semiconductor device package may use wire bond(s) (e.g., aluminum wire bond(s)) for interconnection between portions of the one or more semiconductor die (e.g., a gate contact) and the package (e.g., lead frame). Furthermore, in some examples, a passivation layer may be provided on the one or more semiconductor die, such as a silicon nitride and/or polyimide passivation layer.

The power semiconductor device package may further include a housing in which the one or more semiconductor die may be arranged. The power semiconductor device package may also include one or more electrical leads extending from the housing. More particularly, in some examples, the housing may be an encapsulating portion (e.g., epoxy mold compound (EMC)) formed around at least a portion of the submount and the one or more semiconductor die. The power semiconductor device package may further include one or more metallization structures. A “metallization structure” is any layer, structure, or other portion of a semiconductor die that incorporates a metal for thermal and/or electrical conduction. Metallization structures in a semiconductor device may be used, for instance, to provide an electrically conductive and/or thermally conductive connection to the one or more semiconductor die. The metallization structure may include, for instance, one or more electrodes, contacts, interconnections, bonding pads, backside layers, metal layers, or metal coatings of the semiconductor device on the semiconductor die.

Packaging technology for semiconductor devices plays an important role in defining the performance of the semiconductor devices. For example, the packaging of a power semiconductor device package may limit the ability of the one or more semiconductor die to dissipate heat, conduct current, or even switch at particular speeds (e.g., due to stray inductance). Ineffective heat dissipation can create problems for semiconductor devices (e.g., small form factor semiconductor devices) or in situations where the semiconductor device comes into close contact with the housing. Excessive heat can adversely impact the operation of the semiconductor device itself, as well as the electronic system that uses that semiconductor device.

The packaging of a power semiconductor die may also affect clearance and creepage of the semiconductor device. More particularly, clearance (or “clearance distance”) is the shortest direct path through air between conductors at different voltage potentials. Adequate clearance distances are vital to preventing an ionization of an air gap of the semiconductor device because a breakdown along a clearance path can happen instantaneously under certain operating conditions.

Similarly, creepage (or “creepage distance”) is the shortest direct path along a surface between conductors at different voltage potentials. As such, the packaging of the power semiconductor device plays an important role in determining the creepage distance of the power semiconductor device. Creepage may occur in situations where charge carriers are influenced by, for instance, electric fields, temperature gradients, and/or other factors that cause the charge carriers to drift along the surface of the power semiconductor device. Depending on the packaging and operating conditions of the power semiconductor device, creepage may contribute to leakage currents and/or other non-ideal behaviors in the semiconductor device. Thus, creepage distances are an important design consideration to ensure proper insulation and to prevent electrical breakdown, especially in high-voltage applications that require increased creepage distances.

Accordingly, to reduce the adverse performance-related effects associated with packaging and to increase one or more operating characteristics of the power semiconductor device package (e.g., operating voltage, rated current, etc.), example aspects of the present disclosure are directed to power semiconductor device packages having a housing, a plurality of semiconductor die on a plurality of respective submounts, a plurality of electrical leads extending from the housing, and one or more creepage extension structures (e.g., creepage cutouts) in the housing.

More particularly, a power semiconductor device package of the present disclosure may include a housing (e.g., epoxy mold compound (EMC)). In some examples, the housing may have a plurality of surfaces and/or a plurality of sides. For instance, the housing may include one or more “major” sides and one or more “minor” sides. As used herein, a “major side(s)” and/or a “major surface(s)” refers to a primary (e.g., most significant) surface(s) of the housing, such as the principal face(s) of the housing, the side(s) having the largest surface area, and/or the like. Conversely, a “minor side(s)” and/or a “minor surface(s)” refers to a secondary (e.g., less prominent) surface(s) of the housing relative to the “major side(s),” such as the side surface(s) of the housing, the side(s) having a smaller surface area relative to the principal faces, and/or the like. It should be understood that, when describing the housing, the terms “surface” and “side” may be used interchangeably.

More particularly, the housing may include a first major side (e.g., top side) and a second major side (e.g., bottom side) that is generally opposite the first major side. The first major side and the second major side may be generally parallel relative to one another. The housing may further include one or more minor sides extending between the first major side and the second major side. For instance, in some examples, the housing may include a first minor side (e.g., back-side surface) and a second minor side (e.g., front-side surface) that is generally opposite the first minor side. The first minor side and the second minor side may be generally perpendicular to the first major side and the second major side. The first minor side and the second minor side may be generally parallel relative to one another. The housing may further include a third minor side (e.g., right-side surface) and a fourth minor side (e.g., left-side surface) opposite the third minor side. The third minor side and the fourth minor side may be generally perpendicular to the first major side and the second major side; likewise, the third minor side and the fourth minor side may be perpendicular to the first minor side and the second minor side. The third minor side and the fourth minor side may be generally parallel relative to one another.

The power semiconductor device package of the present disclosure may include a plurality of semiconductor die at least partially within the housing, such as a first semiconductor die and a second semiconductor die. For instance, in some examples, the first semiconductor die and the second semiconductor die may be co-planar and may be arranged within the housing. In this way, the first semiconductor die may define a first portion of the housing, and the second semiconductor die may define a second portion of the housing. Furthermore, in some examples, the first semiconductor die may be electrically isolated from the second semiconductor die. Those having ordinary skill in the art, using the disclosures provided herein, will understand that power semiconductor device packages of the present disclosure may include more than two semiconductor die within the housing without deviating from the scope of the present disclosure.

In some examples, the first semiconductor die may be on a first submount. Likewise, the second semiconductor die may be on a second submount. In some examples, the first submount may include (or may be) a first conductive structure, and the second submount may include (or may be) a second conductive structure. In such examples, the first conductive structure and the second conductive structure may be thermally conductive. Additionally and/or alternatively, in some examples, the first conductive structure and the second conductive structure may be electrically conductive.

In some examples, the first submount may be a first power substrate, and the second submount may be a second power substrate. In such examples, at least a portion of the first power substrate may be at least partially exposed through a major side of the housing to provide a heat dissipation path (e.g., cooling path) for the first semiconductor die. Likewise, at least a portion of the second power substrate may be at least partially exposed through the major side of the housing to provide a heat dissipation path (e.g., cooling path) for the second semiconductor die. As will be discussed in greater detail below, power substrates, such as direct bonded copper (DBC) substrate and/or active metal brazed (AMB) substrates, may include a plurality of metal layers and an insulating layer between the metal layers.

In some examples, the first submount may be a first lead frame, and the second submount may be a second lead frame. In such examples, at least a portion of the first lead frame may be at least partially exposed through a major side of the housing to provide a heat dissipation path (e.g., cooling path) for the first semiconductor die. Likewise, at least a portion of the second lead frame may be at least partially exposed through the major side of the housing to provide a heat dissipation path (e.g., cooling path) for the second semiconductor die.

Furthermore, in some examples, the first lead frame may be on a first power substrate, and the second lead frame may be on a second power substrate. In such examples, at least a portion of the first power substrate may be at least partially exposed through the major side of the housing, and at least a portion of the second power substrate may be at least partially exposed through the major side of the housing.

The power semiconductor device package may further include a plurality of electrical leads extending from the housing. More particularly, a power semiconductor device package of the present disclosure may incorporate surface-mount technology connection structures. For instance, by way of non-limiting example, the plurality of electrical leads extending from the housing may be a plurality of surface mount type (SMT) connection structures, a plurality of Gull-wing pins, and/or the like.

More particularly, the power semiconductor device package may include a first plurality of electrical leads coupled to the first semiconductor die and extending from the housing. The first plurality of electrical leads may include a first lead coupled to a source contact of the first semiconductor die, a second lead coupled to a gate contact of the first semiconductor die, and a third lead coupled to a drain contact of the first semiconductor die. In some examples, the first plurality of electrical leads may include a fourth lead coupled to an additional contact of the first semiconductor die, such as a kelvin contact, a sensor contact, and/or another suitable contact.

The power semiconductor device package may further include a second plurality of electrical leads coupled to the second semiconductor die and extending from the housing. The second plurality of electrical leads may include a first lead coupled to a source contact of the second semiconductor die, a second lead coupled to a gate contact of the second semiconductor die, and a third lead coupled to a drain contact of the second semiconductor die. In some examples, the second plurality of electrical leads may include a fourth lead coupled to an additional contact of the first semiconductor die, such as a kelvin contact, a sensor contact, and/or another suitable contact.

As will be described in greater detail below, in some examples, the second plurality of electrical leads may have an inverse configuration relative to the first plurality of electrical leads. For instance, in some examples, the first plurality of electrical leads may extend from the first portion of the housing (e.g., defined by the first semiconductor die), and the second plurality of electrical leads may extend from the second portion of the housing (e.g., defined by the second semiconductor die). Moreover, in some examples, the second plurality of electrical leads may be rotated approximately 180 degrees (e.g., along a housing plane defined by one of the major sides of the housing) relative to the first plurality of electrical leads. For instance, by way of non-limiting example, the first lead (e.g., source lead) and the second lead (e.g., gate lead) of the first plurality of electrical leads may extend from the first minor side of the housing, and the third lead (e.g., drain lead) of the first plurality of electrical leads may extend from the second minor side of the housing; conversely, the first lead (e.g., source lead) and the second lead (e.g., gate lead) of the second plurality of electrical leads may extend from the second minor side of the housing, and the third lead (e.g., drain lead) of the second plurality of electrical leads may extend from the first minor side of the housing.

Although described herein as including a plurality of electrical leads, those having ordinary skill in the art, using the disclosures provided herein, will understand that power semiconductor device packages of the present disclosure may include any suitable connection structure (e.g., pin, terminal, contact, interconnect, bonding pad, and/or the like) without deviating from the scope of the present disclosure.

As described above, the first submount may be or may include a first conductive structure, and the second semiconductor die may be or may include a second conductive structure. In some examples, the first conductive structure and the second conductive structure may provide for cooling of the power semiconductor device package. More particularly, in some examples, the first conductive structure and the second conductive structure may be at least partially exposed through the first major side of the housing (e.g., top-side cooling). Additionally and/or alternatively, in some examples, the first conductive structure and the second conductive structure may be at least partially exposed through the second major side of the housing (e.g., bottom-side cooling). Additionally and/or alternatively, in some examples, the first conductive structure and the second conductive structure may be on, and/or at least partially exposed through, the first major side of the housing, and the power semiconductor device package may further include a third conductive structure (e.g., coupled to and/or integral with the first submount) and a fourth conductive structure (e.g., coupled to and/or integral with the second submount) on, and/or at least partially exposed through, the second major side of the housing (e.g., dual-side cooling).

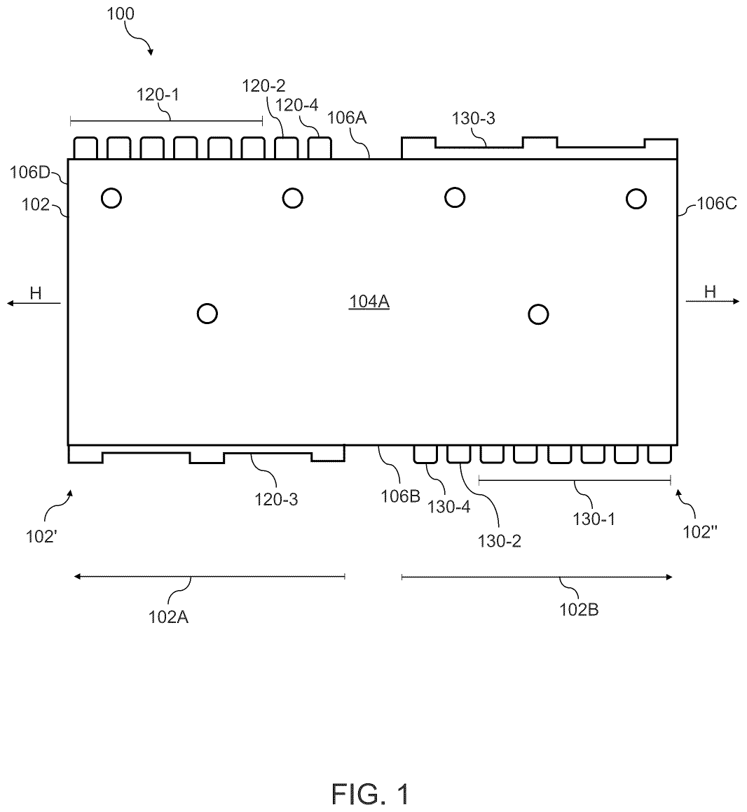

As used herein, a “bottom-side cooling” or “bottom-side cooled” power semiconductor device package refers to a power semiconductor device package configured to dissipate heat through a bottom side and/or bottom surface (e.g., second major side) of the power semiconductor device package. “Bottom-side cooled” power semiconductor device packages are depicted in, and described with reference to, FIG. 1-9, 20-22 of the present disclosure.

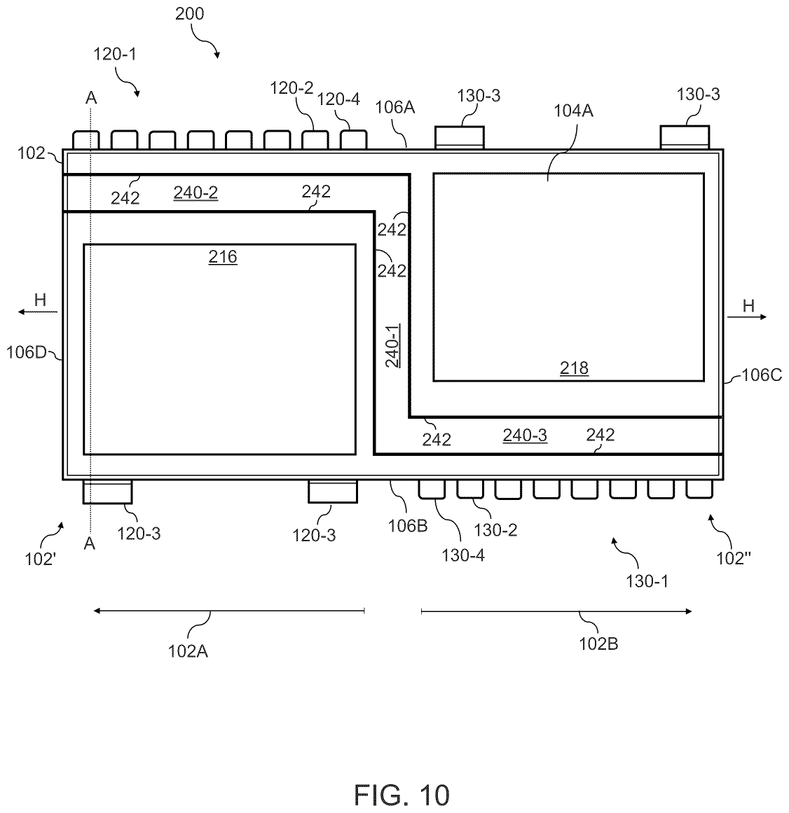

As used herein, a “top-side cooling” or “top-side cooled” power semiconductor device package refers to a power semiconductor device package configured to dissipate heat through a top side and/or top surface (e.g., first major side) of the power semiconductor device package. “Top-side cooled” power semiconductor device packages are depicted in, and described with reference to, FIG. 10-15 of the present disclosure.

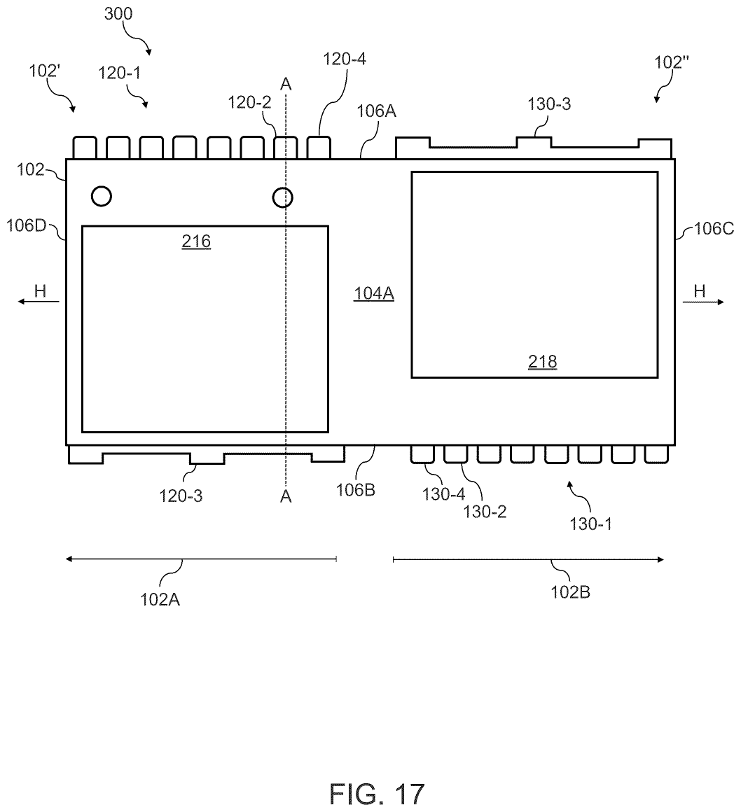

As used herein, a “dual-side cooling” or “dual-side cooled” power semiconductor device package refers to a power semiconductor device package configured to dissipate heat through a top side and/or top surface (e.g., first major side) and a bottom side and/or bottom surface (e.g., second major side) of the power semiconductor device package. “Dual-side cooled” power semiconductor device packages are depicted in, and described with reference to, FIG. 17-19 of the present disclosure.

In some examples, the first conductive structure may include a thermal pad that is electrically isolated from the first plurality of electrical leads. For instance, the first conductive structure may be coupled to a drain contact of the first semiconductor die. The first conductive structure may also be electrically isolated from the first semiconductor die and the second semiconductor die. For instance, in some examples, the first conductive structure may be on an insulating layer of a mounting substrate of the first semiconductor die. Furthermore, in some examples, the first conductive structure may further include an electrically insulating plate (e.g., DBC plate, AMB plate, etc.) arranged on the thermal pad. Hence, in some examples, the first conductive structure may allow for direct attachment to a heat sink (e.g., with an electrical isolator) to enhance thermal performance.

Likewise, the second conductive structure may include a thermal pad that is electrically isolated from the second plurality of electrical leads. For instance, the second conductive structure may be coupled to a drain contact of the second semiconductor die. The second conductive structure may also be electrically isolated from the first semiconductor die and the second semiconductor die. For instance, in some examples, the second conductive structure may be on an insulating layer of a mounting substrate of the second semiconductor die. Furthermore, in some examples, the second conductive structure may further include an electrically insulating plate (e.g., DBC plate, AMB plate, etc.) arranged on the thermal pad. Hence, in some examples, the second conductive structure may allow for direct attachment to a heat sink (e.g., with an electrical isolator) to enhance thermal performance.

The power semiconductor device package may further include a creepage extension structure (e.g., creepage cutout, creepage feature, etc.) in the housing. For instance, in some examples, the power semiconductor device package may include a creepage extension structure in the housing between the first semiconductor die and the second semiconductor die (e.g., between the first plurality of electrical leads and the second plurality of electrical leads). That is, in some examples, the creepage extension structure may be between the first submount and the second submount. As will be discussed in greater detail below, in such examples, the creepage extension structure between the first semiconductor die and the second semiconductor die may provide the power semiconductor device package with increased creepage distance(s), thereby reducing the adverse performance-related effects discussed above and increasing the current and voltage handling capabilities of the power semiconductor device package.

It should be understood that, when used with respect to an arrangement of the creepage extension structure, the term “between” refers to the two-dimensional arrangement along the housing plane (e.g., defined by one of the major sides of the housing). That is, the creepage extension structure may be between a first semiconductor die and a second semiconductor die when the power semiconductor device package is viewed from a top plan view and/or a bottom plan view. In some examples, the creepage extension structure may be “between” a first semiconductor die and a second semiconductor die despite being above and/or below the first semiconductor die and the second semiconductor die when viewed from a cross-sectional side view.

The creepage extension structure may have any suitable shape and/or configuration. By way of non-limiting example, the creepage extension structure may be a rectangular creepage extension structure and/or a non-rectangular creepage extension structure. For instance, in some examples, the creepage extension structure may be a step structure between the first semiconductor die and the second semiconductor die. Additionally and/or alternatively, in some examples, the creepage extension structure may be a trench defined between the first semiconductor die and the second semiconductor die. Furthermore, the creepage extension structure may have any suitable number of sidewall segments, such as at least two sidewall segments, such as at least six sidewall segments, such as at least eight sidewall segments, etc.

By way of non-limiting example, the creepage extension structure provided in the housing may include one or more creepage portions. For instance, in some examples, the creepage extension structure may include one creepage portion. In such examples, the creepage extension structure may extend along a major side (e.g., first major side, second major side) of the housing from the first minor side (e.g., back side) of the housing to the second minor side (e.g., front side) of the housing. Put differently, the creepage extension structure may extend along the major side of the housing between the first semiconductor die and the second semiconductor die (e.g., between the first plurality of electrical leads and the second plurality of electrical leads).

Additionally and/or alternatively, in some examples, the creepage extension structure may include a plurality of creepage portions. For instance, in some examples, the creepage extension structure may include a first creepage portion, a second creepage portion, and a third creepage portion. More particularly, the first creepage portion of the creepage extension structure may be between the first semiconductor die and the second semiconductor die; the first creepage portion may extend along a major side (e.g., first major side, second major side) of the housing from the first minor side (e.g., back side) of the housing to the second minor side (e.g., front side) of the housing. The second creepage portion of the creepage extension structure may be perpendicular to the first creepage portion and may extend laterally along the major surface between the first creepage portion and a first peripheral end of the housing (e.g., towards the fourth minor side). The third creepage portion of the creepage extension structure may be perpendicular to the first creepage portion and may extend laterally along the major surface between the first creepage portion and a second peripheral end of the housing (e.g., towards the third minor side). Put differently, although both extend laterally away from the first creepage portion, the second creepage portion and the third creepage portion of the creepage extension structure may laterally extend in opposite directions (e.g., away from the first creepage portion). In this manner, the first creepage portion of the creepage extension structure may provide a creepage distance between the first semiconductor die and the second semiconductor die, the second creepage portion of the creepage extension structure may provide a creepage distance between the first (e.g., source) lead and the third (e.g., drain) lead of the first plurality of electrical leads, and the third creepage portion of the creepage extension structure may provide a creepage distance between the first (e.g., source) lead and the third (e.g., drain) lead of the second plurality of electrical leads.

In some examples, the power semiconductor device package may include more than one creepage extension structure. By way of non-limiting example, the creepage extension structure described above may be a first creepage extension structure, and the power semiconductor device package may further include a second creepage extension structure in the housing on an opposing major side of the housing from the first creepage extension structure.

For instance, in some examples, the second creepage extension structure may provide a creepage distance between a drain contact of the first semiconductor die and a source contact of the second semiconductor die. Additionally and/or alternatively, in some examples, the power semiconductor device package may further include a third creepage extension structure in the housing on the same major side of the housing as the second creepage extension structure (e.g., on the opposing major side from the first creepage extension structure). For instance, in some examples, the third creepage extension structure may provide a creepage distance between a source contact of the first semiconductor die and a drain contact of the second semiconductor die. Furthermore, in some examples, the second creepage extension structure may have a same shape and/or configuration as the third creepage extension structure. In other examples, the second creepage extension structure may have a different shape and/or configuration than the third creepage extension structure.

Aspects of the present disclosure provide a number of technical effects and benefits. For instance, power semiconductor device packages of the present disclosure may include multiple semiconductor die (respectively) coupled to multiple submounts (e.g., lead frames) within the same housing. As such, example aspects of the present disclosure provide a compact and cost-effective power semiconductor device package with a reduced form factor, while simultaneously providing for increased current-and voltage-handling capabilities relative to other semiconductor device packages having similarly small form factors. Furthermore, by incorporating surface-mount technology structures (e.g., SMT connection structures, Gull-wing pins, etc.), example aspects of the present disclosure provide enhanced flexibility with different pin-out options for the plurality of electrical leads. Additionally, by coupling conductive submounts to the semiconductor die, example aspects of the present disclosure allow for efficient thermal dissipation along the corresponding major side of the housing (e.g., top-side cooling, bottom-side cooling), thereby enhancing thermal performance and heat dissipation efficiency.

Moreover, by providing a creepage extension structure (e.g., creepage feature, etc.) in the housing, power semiconductor device packages of the present disclosure may provide a high voltage rating and/or a high current rating due to the increased creepage distance resulting from the creepage extension structure. As such, the creepage extension structure ensures proper insulation and reduces electrical breakdown in high-voltage semiconductor devices. In this way, example aspects of the present disclosure provide increased current and voltage capabilities for semiconductor packages (e.g., discrete power semiconductor packages), thereby providing for increased reliability and longevity of high-voltage semiconductor devices.

It will be understood that, although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present, except in some examples an attach material (e.g., die-attach material, solder, paste, adhesive, sintered material or other material may be present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present, except in some examples an attach material (e.g., die-attach material, solder, paste, adhesive, sintered material or other material may be present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to silicon carbide-based semiconductor structures, such as silicon carbide-based MOSFETs. Those of ordinary skill in the art, using the disclosures provided herein, will understand that the power semiconductor packages according to example embodiments of the present disclosure may be used with any semiconductor material, such as other wide band gap semiconductor materials, without deviating from the scope of the present disclosure. Example wide band gap semiconductor materials include silicon carbide (e.g., 2.996 eV band gap for alpha silicon carbide at room temperature) and the Group III-nitrides (e.g., 3.36 eV band gap for gallium nitride at room temperature).

In the drawings and specification, there have been disclosed typical embodiments and, although specific terms are employed, they are used in a generic and descriptive sense only and not for purposes of limitation of the scope set forth in the following claims.

FIG. 1-9 depict an example bottom-side cooled power semiconductor device package 100 according to example embodiments of the present disclosure. As will be discussed in greater detail below, the power semiconductor device package 100 is configured to dissipate heat through its bottom side and/or bottom surface. It should be understood that FIG. 1-9 are intended to represent structures for purposes of identification and description and are not intended to represent the structures to physical scale.

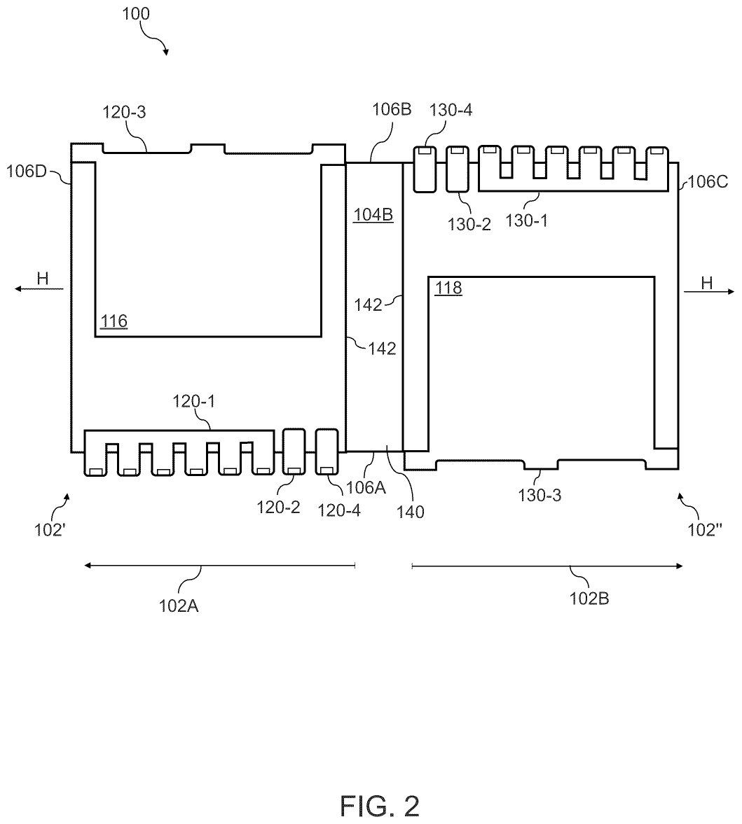

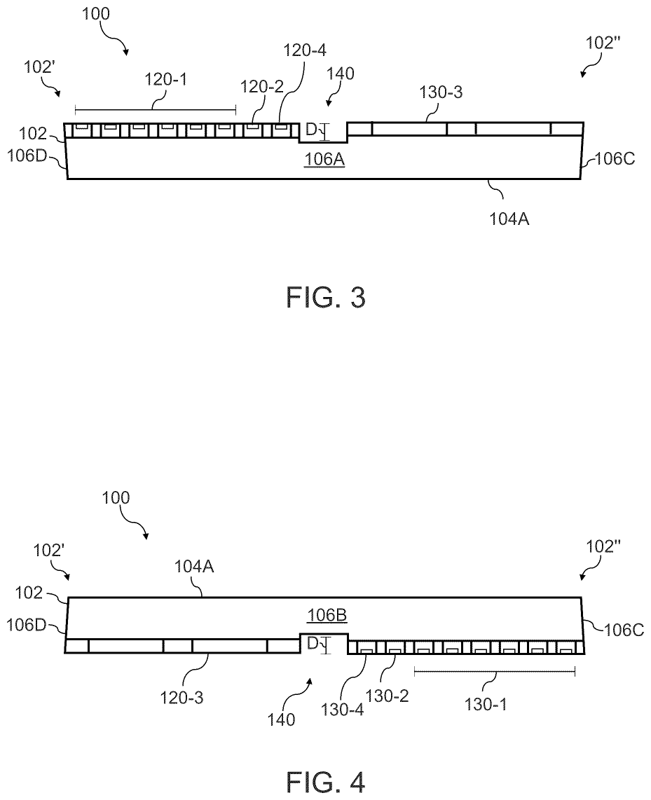

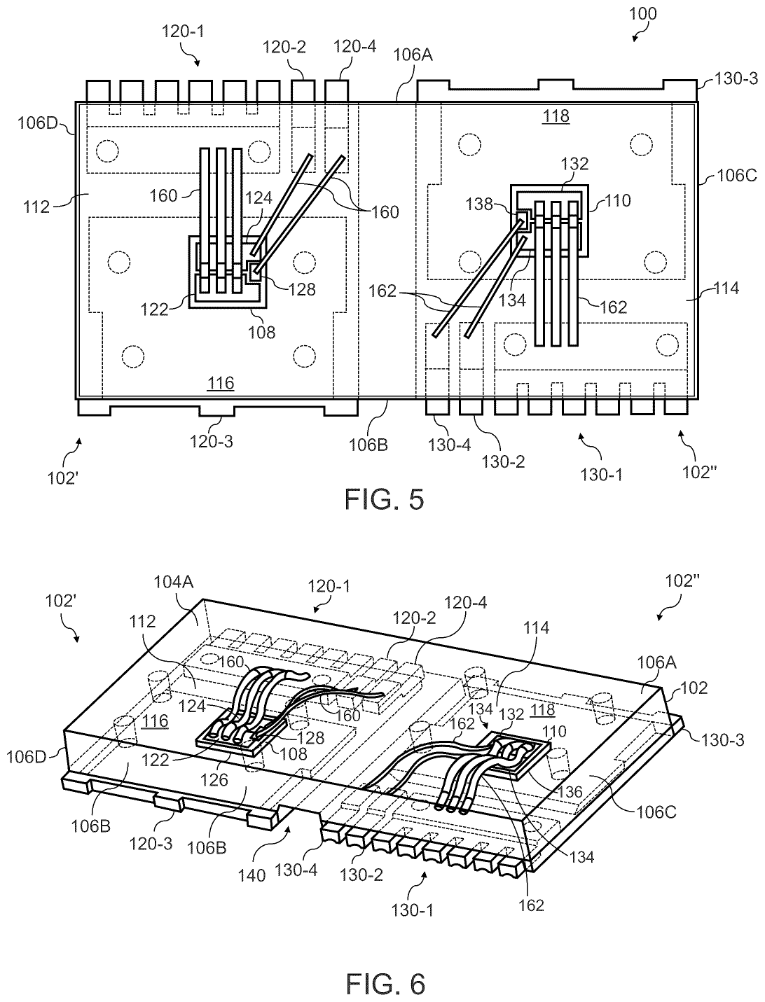

Referring now to FIG. 1-6, FIG. 1 depicts a top plan view of the power semiconductor device package 100, FIG. 2 depicts a bottom plan view of the power semiconductor device package 100, and FIG. 3-4 depict side plan views of the power semiconductor device package 100. Furthermore, FIG. 5 depicts a top wireframe view of the power semiconductor device package 100 and FIG. 6 depicts a perspective wireframe view of the power semiconductor device package 100.

As shown, the power semiconductor device package 100 includes a housing 102. The housing 102 may be formed by a molding process. The housing 102 may include a material capable of high temperature operation, such as a temperature of about 200° C. Example materials for the housing 102 may include an epoxy material or an epoxy mold compound (EMC).

The housing 102 may include one or more surfaces and/or one or more sides. For instance, the housing may include one or more “major” sides 104 and one or more “minor” sides 106. As noted above, a “major side(s)” and/or a “major surface(s)” refers to a primary (e.g., most significant) surface(s) of the housing 102, such as the principal face(s) of the housing 102, the side(s) having the largest surface area, and/or the like. Conversely, a “minor side(s)” and/or a “minor surface(s)” refers to a secondary (e.g., less prominent) surface(s) of the housing 102 relative to the “major side(s),” such as the side surface(s) of the housing 102, the side(s) having a smaller surface area relative to the principal faces, and/or the like. It should be understood that, when describing the housing 102, the terms “surface” and “side” may be used interchangeably.

For instance, as shown, the housing 102 may include a first major side 104A (e.g., top side) (FIG. 1) and a second major side 104B (e.g., bottom side) (FIG. 2). The second major side 104B may be generally opposite the first major side 104A. The first major side 104A and the second major side 104B may be generally parallel relative to one another. As shown in FIG. 1-2, the first major side 104A and the second major side 104B may be the principal faces of the housing 102 and, as such, may define a housing plane H for the housing 102.

The housing 102 may further include one or more minor sides 106 extending between the first major side 104A and the second major side 104B. For instance, as shown, the housing 102 may include a first minor side 106A (e.g., back-side surface) (FIG. 4) and a second minor side 106B (e.g., front-side surface). The second minor side 106B may be generally opposite the first minor side 106A. The first minor side 106A and the second minor side 106B may be generally perpendicular to the first major side 104A and the second major side 104B. The first minor side 106A and the second minor side 106B may be generally parallel relative to one another. The housing 102 may further include a third minor side 106C (e.g., right-side surface) and a fourth minor side 106D (e.g., left-side surface). The fourth minor side 106D (e.g., defining a first peripheral end 102′of the housing 102) may be generally opposite the third minor side 106C (e.g., defining a second peripheral end 102″ of the housing 102). The third minor side 106C and the fourth minor side 106D may be generally perpendicular to the first major side 104A and the second major side 104B; likewise, the third minor side 106C and the fourth minor side 106D may be perpendicular to the first minor side 106A and the second minor side 106B. The third minor side 106C and the fourth minor side 106D may be generally parallel relative to one another.

It should be understood that the housing 102 may include different arrangements of surfaces without deviating from the scope of the present disclosure. For instance, one or more notches and/or one or more recesses may be formed on any of the sides and/or surfaces of the housing 102 without deviating from the scope of the present disclosure.

In some examples, the power semiconductor device package 100 may be arranged as a surface mount technology package. More particularly, in some examples, the first major side 104A of the housing 102 may be positioned opposite an external surface, such as a printed circuit board (PCB) on which the power semiconductor device package 100 is mounted. In such examples, the second major side 104B forms a mounting side of the power semiconductor device package 100 that is mounted to the external surface (e.g., PCB). Additionally and/or alternatively, in other examples, the second major side 104B of the housing 102 may be positioned opposite the external surface (e.g., PCB). In such examples, the first major side 104A forms the mounting side of the power semiconductor device package 100 that is mounted to the external surface (e.g., PCB).

The power semiconductor device package 100 may be arranged to house and provide external connections to one or more semiconductor die. For instance, referring briefly to FIG. 5-6, the power semiconductor device package 100 may include a first semiconductor die 108 and a second semiconductor die 110. As shown, the first semiconductor die 108 and the second semiconductor die 110 may be arranged within the housing 102. Hence, the first semiconductor die 108 may define a first portion 102A of the housing 102 (e.g., a first subpackage), and the second semiconductor die 110 may define a second portion 102B of the housing 102 (e.g., a second subpackage). It should be understood that the power semiconductor device package 100 is depicted in FIG. 1-6 as having two semiconductor die (e.g., first semiconductor die 108, second semiconductor die 110) for purposes of illustration and discussion. Those having ordinary skill in the art, using the disclosures provided herein, will understand that example power semiconductor device packages of the present disclosure may have more than two semiconductor die without deviating from the scope of the present disclosure.

Referring still to FIG. 5-6, the first semiconductor die 108 may be mounted on a mounting substrate, such as a first submount 112 (e.g., conductive lead frame). The first semiconductor die 108 may be coupled to the first submount 112 with, for instance, a die-attach material. In some examples, the first semiconductor die 108 may be directly coupled to the first submount 112. Likewise, the second semiconductor die 110 may be mounted on a mounting substrate, such as a second submount 114 (e.g., conductive lead frame). The second semiconductor die 110 may be coupled to the second submount 114 with, for instance, a die-attach material. In some examples, the second semiconductor die 110 may be directly coupled to the second submount 114. As will be discussed in greater detail below, in some examples, the first submount 112 may be a first lead frame, and the second submount 114 may be a second lead frame. Additionally and/or alternatively, in some examples, the first submount 112 may be a first power substrate, and the second submount 114 may be a second power substrate.

In some examples, the first semiconductor die 108 and the second semiconductor die 110 may include a wide bandgap semiconductor material, such as silicon carbide (SiC), a Group-III nitride (e.g, gallium nitride (GaN)), and/or the like. Furthermore, the first semiconductor die 108 and the second semiconductor die 110 may include one or more semiconductor devices, such as metal-oxide-semiconductor field-effect transistor (MOSFET) devices, Schottky diodes, and/or other devices. For instance, referring still to FIG. 5-6, the first semiconductor die 108 and the second semiconductor die 110 may include silicon carbide-based MOSFETs. In such examples, the first semiconductor die 108 may include a source contact 122, a gate contact 124, and a drain contact 126. In some examples, the first semiconductor die 108 may further include an additional contact 128, such as a source-Kelvin contact, a sensor contact, and/or the like. Likewise, in such examples, the second semiconductor die 110 a source contact 132, a gate contact 134, and a drain contact 136. In some examples, the second semiconductor die 110 may further include an additional contact 138, such as a source-Kelvin contact, a sensor contact, and/or the like.

As shown in FIG. 5-6, in some examples, the first semiconductor die 108 and the second semiconductor die 110 may be electrically isolated from one another. Additionally and/or alternatively, in other examples, the power semiconductor device package 100 may include one or more die-to-die interfaces coupling the first semiconductor die 108 to the second semiconductor die 110.

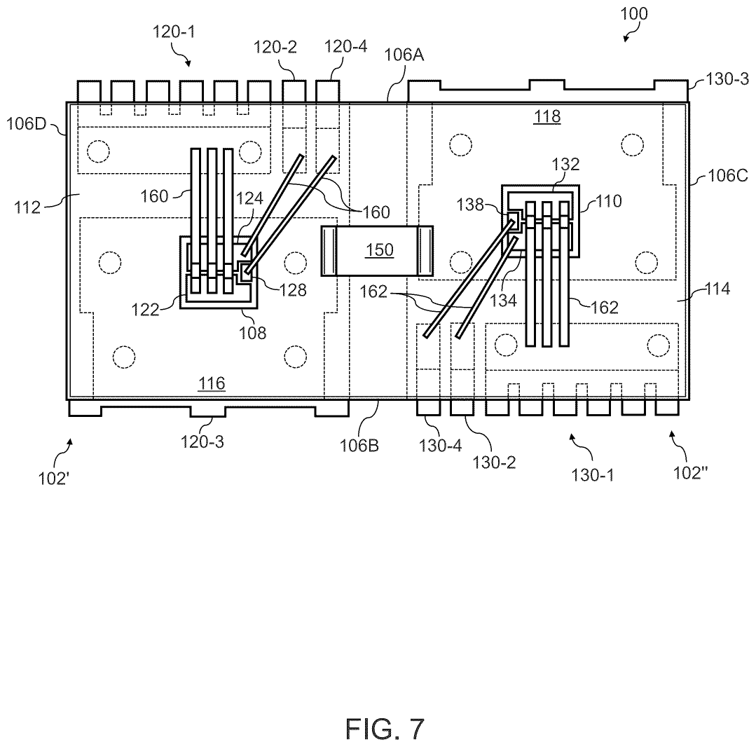

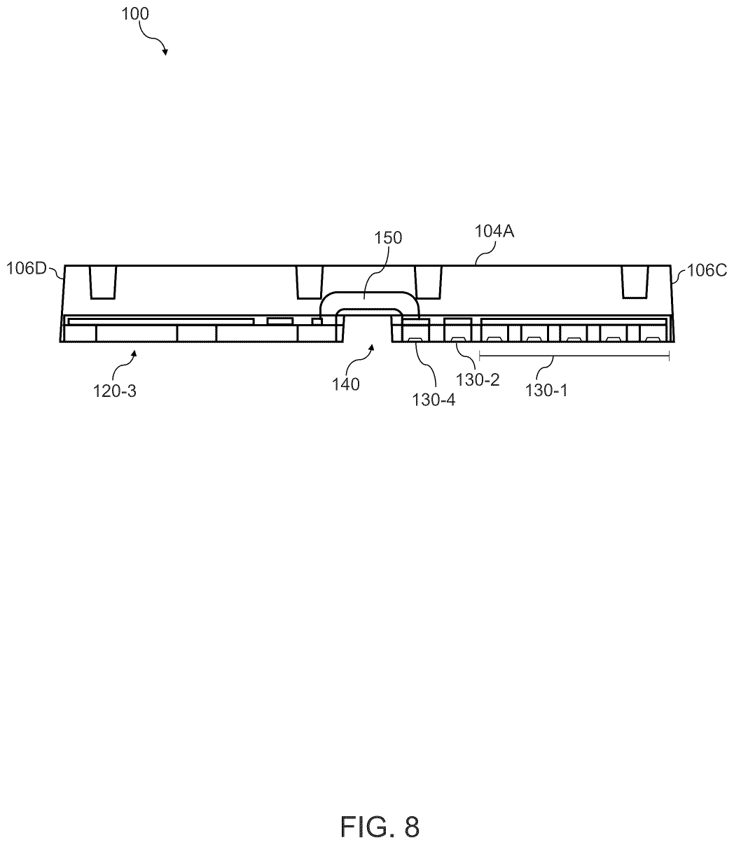

As one illustrative example, FIG. 7-8 depict wireframe views of the example power semiconductor device package 100 according to example embodiments of the present disclosure. More particularly, FIG. 7 depicts a top wireframe view of the power semiconductor device package 100, and FIG. 8 depicts a side wireframe view of the power semiconductor device package 100. As shown, in some examples, the power semiconductor device package 100 may include an interface 150 coupling the first semiconductor die 108 to the second semiconductor die 110. In the example depicted in FIG. 7-8, the drain contact 126 of the first semiconductor die 108 is coupled to the drain contact 136 of the second semiconductor die 110. Hence, in some examples, the first semiconductor die 108 and the second semiconductor die 110 may have a common drain.

Aspects of the present disclosure are discussed with reference to silicon carbide-based MOSFET devices for purposes of illustration and discussion. Those having ordinary skill in the art, using the disclosures provided herein, will understand that the power semiconductor device packages described herein may include other power semiconductor devices without deviating from the scope of the present disclosure, such as diodes (e.g., Schottky diodes, PiN diodes, etc.), insulated gate bipolar transistors, high electron mobility transistors (HEMTs), and/or other devices. For instance, in some implementations, the first semiconductor die 108 and the second semiconductor die 110 disposed within the housing 102 may include a silicon-carbide based Schottky diode. Additionally and/or alternatively, in some implementations, the first semiconductor die 108 and the second semiconductor die 110 disposed within the housing 102 may include a Group-III nitride-based HEMT.

Referring again to FIG. 1-6, the power semiconductor device package 100 may include a first conductive structure 116 and a second conductive structure 118. More particularly, the first submount 112 may be and/or may include the first conductive structure 116, and the second submount 114 may be and/or may include the second conductive structure 118.

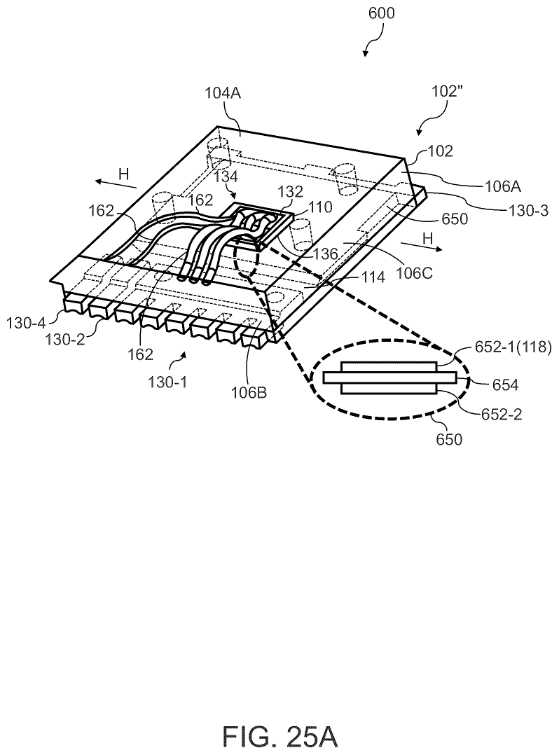

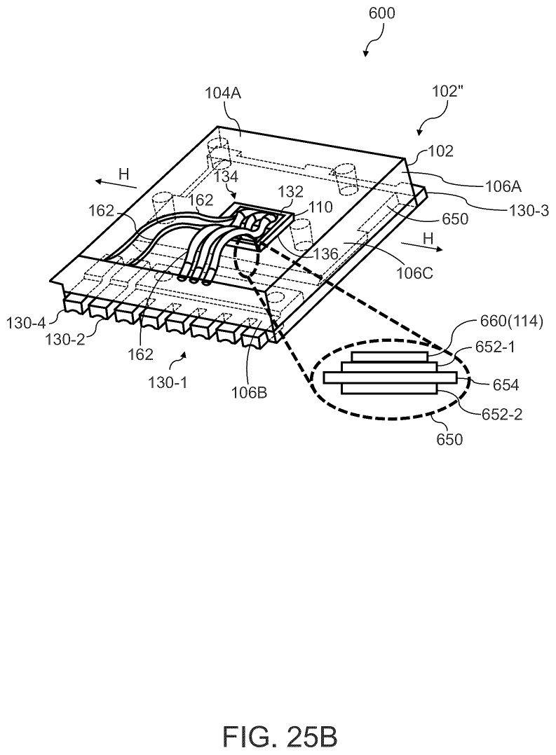

Furthermore, the first conductive structure 116 may be coupled to the drain contact 126 of the first semiconductor die 108, and the second conductive structure 118 may be coupled to the drain contact 136 of the second semiconductor die 110. As will be discussed in greater detail below (e.g., FIG. 25A-25B), in some examples, the first submount 112 and the second submount 114 may be part of a first power substrate and a second power substrate (respectively) that each include a plurality of metal layers and an insulating layer between the metal layer.

The first conductive structure 116 and the second conductive structure 118 may provide a heat dissipation path for the first semiconductor die 108 and the second semiconductor die 110 (respectively) through the second major side 104B of the housing 102. More particularly, the first conductive structure 116 and the second conductive structure 118 may include or be coupled to a thermally conductive and/or electrically conductive material, such as a metal. In some examples, the first conductive structure 116 and the second conductive structure 118 may be coupled to an external heat sink (e.g., with an electrical isolator) to provide for cooling of the power semiconductor device package 100. For instance, the first conductive structure 116 and the second conductive structure 118 may, in some examples, be at least partially exposed through the second major side 104B of the housing 102 (e.g., FIG. 1-9, 17-19). Hence, the first conductive structure 116 and the second conductive structure 118 may provide for bottom-side cooling of the power semiconductor device package 100.

As will be discussed in greater detail below, in some examples (e.g., FIG. 10-15), power semiconductor device packages of the present disclosure may include one or more conductive structures operable to provide a heat dissipation path for the first semiconductor die 108 and the second semiconductor die 110 through the first major side 104A of the housing 102 (e.g., “top-side” cooling). Additionally and/or alternatively, in some examples (e.g., FIG. 17-19), power semiconductor device packages of the present disclosure may include one or more conductive structures operable to provide a heat dissipation path for the first semiconductor die 108 and the second semiconductor die 110 through both the first major side 104A and the second major side 104B of the housing 102 (e.g., “dual-side” cooling).

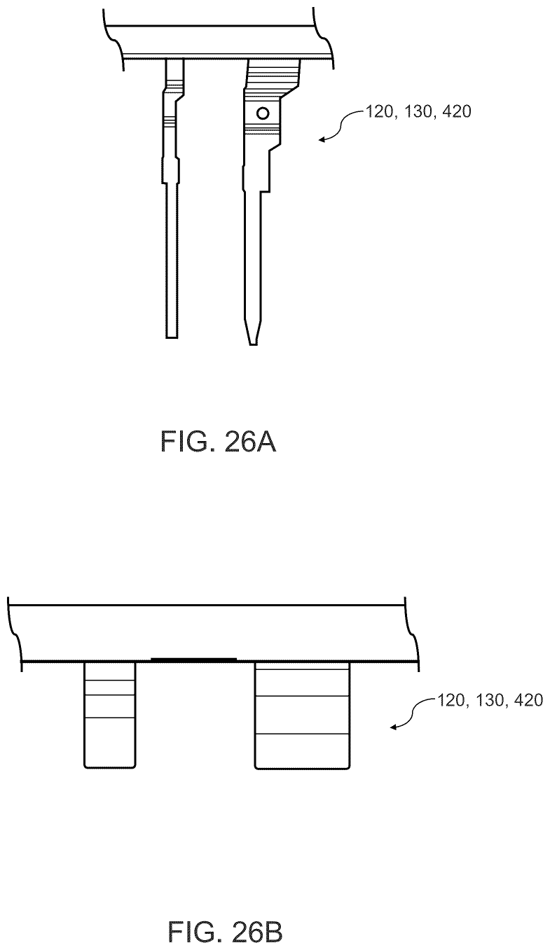

Referring still to FIG. 1-6, the power semiconductor device package 100 may include a first plurality of electrical leads 120 extending from the first portion 102A of the housing 102. As shown, the first plurality of electrical leads 120 may be partially encapsulated by the housing 102 such that a portion of each of the first plurality of electrical leads 120 is exposed through the first portion 102A of the housing 102. The first plurality of electrical leads 120 may be coupled to the first semiconductor die 108 and may have the form of electrical connection pins, such as surface mount type (SMT) connection structures. It should be understood that, although depicted as a plurality of leadless SMT connection structures, the first plurality of electrical leads 120 may have any suitable electrical connection pin, such as extended leads (FIG. 26A), Gull-wing pins (FIG. 26B), and/or the like.

In the example of the first semiconductor die 108 including a silicon carbide-based MOSFET, the first plurality of electrical leads 120 may include at least one first lead 120-1, at least one second lead 120-2, and at least one third lead 120-3. In some examples, the first plurality of electrical leads 120 may further include one or more additional leads, such as one or more fourth leads 120-4. Those having ordinary skill in the art, using the disclosures provided herein, will understand that the first plurality of electrical leads 120 may include more, or fewer, electrical leads without deviating from the scope of the present disclosure.

More particularly, the first lead 120-1 of the first plurality of electrical leads 120 may include an electrical connection pin. The first lead 120-1 may be coupled to the source contact 122 (FIG. 5-6) of the first semiconductor die 108. In some examples, the first lead 120-1 may be coupled to the source contact 122 using, for instance, one or more wire bonds 160. In this way, the first lead 120-1 of the first plurality of electrical leads 120 may be used to connect the source of the MOSFET on the first semiconductor die 108 to one or more external connections.

The second lead 120-2 of the first plurality of electrical leads 120 may include an electrical connection pin. The second lead 120-2 may be coupled to the gate contact 124 (FIG. 5-6) of the first semiconductor die 108. In some examples, the second lead 120-2 may be coupled to the gate contact 124 using, for instance, one or more wire bonds 160. In this way, the second lead 120-2 of the first plurality of electrical leads 120 may be used to connect the gate of the MOSFET on the first semiconductor die 108 to one or more external connections.

The third lead 120-3 of the first plurality of electrical leads 120 may include an electrical connection pin. The third lead 120-3 may be coupled to the drain contact 126 (FIG. 5- 6) of the first semiconductor die 108. As shown, the drain contact 126 may, in some examples, be on an opposing side of the first semiconductor die 108 relative to the source contact 122 and the gate contact 124. In some examples, the third lead 120-3 may be coupled to the drain contact 126 using, for instance, one or more wire bond(s) (not shown). In this way, the third lead 120-3 of the first plurality of electrical leads 120 may be used to connect the drain of the MOSFET on the first semiconductor die 108 to one or more external connections.

The fourth lead 120-4 of the first plurality of electrical leads 120 may include an electrical connection pin. In some examples, the fourth lead 120-4 may be coupled to the additional contact 128 (FIG. 5- 6) of the first semiconductor die 108. In some examples, the fourth lead 120-4 may be coupled to the additional contact 128 using, for instance, one or more wire bonds 160. As noted above, the additional contact 128 of the first semiconductor die 108 may be a source-Kelvin contact, a sensor contact, and/or the like. In this way, the fourth lead 120-4 of the first plurality of electrical leads 120 may be used to connect the additional contact 128 of the MOSFET on the first semiconductor die 108 to one or more external connections.

It should be understood that the arrangement of the leads 120-1-120-4 of the first plurality of electrical leads 120 is for purposes of illustration and discussion. Those having ordinary skill in the art, using the disclosures provided herein, will understand that the leads 120-1-120-4 of the first plurality of electrical leads 120 may be rearranged, adjusted, etc. without deviating from the scope of the present disclosure.

Referring still to FIG. 1-6, the power semiconductor device package 100 may include a second plurality of electrical leads 130 extending from the second portion 102B of the housing 102. As shown, the second plurality of electrical leads 130 may be partially encapsulated by the housing 102 such that a portion of each of the second plurality of electrical leads 130 is exposed through the second portion 102B of the housing 102. The second plurality of electrical leads 130 may be coupled to the second semiconductor die 110 and may have the form of electrical connection pins, such as surface mount type (SMT) connection structures. It should be understood that, although depicted as a plurality of leadless SMT connection structures, the second plurality of electrical leads 130 may have any suitable electrical connection pin, such as extended leads (FIG. 26A), Gull-wing pins (FIG. 26B), and/or the like.

In the example of the second semiconductor die 110 including a silicon carbide-based MOSFET, the second plurality of electrical leads 130 may include at least one first lead 130-1, at least one second lead 130-2, and at least one third lead 130-3. In some examples, the second plurality of electrical leads 130 may further include one or more additional leads, such as one or more fourth leads 130-4. Those having ordinary skill in the art, using the disclosures provided herein, will understand that the second plurality of electrical leads 130 may include more, or fewer, electrical leads without deviating from the scope of the present disclosure.

More particularly, the first lead 130-1 of the second plurality of electrical leads 130 may include an electrical connection pin. The first lead 130-1 may be coupled to the source contact 132 (FIG. 5-6) of the second semiconductor die 110. In some examples, the first lead 130-1 may be coupled to the source contact 132 using, for instance, one or more wire bonds 162. In this way, the first lead 130-1 of the second plurality of electrical leads 130 may be used to connect the source of the MOSFET on the second semiconductor die 110 to one or more external connections.

The second lead 130-2 of the second plurality of electrical leads 130 may include an electrical connection pin. The second lead 130-2 may be coupled to the gate contact 134 (FIG. 5-6) of the second semiconductor die 110. In some examples, the second lead 130-2 may be coupled to the gate contact 134 using, for instance, one or more wire bonds 162. In this way, the second lead 130-2 of the second plurality of electrical leads 130 may be used to connect the gate of the MOSFET on the second semiconductor die 110 to one or more external connections.

The third lead 130-3 of the second plurality of electrical leads 130 may include an electrical connection pin. The third lead 130-3 may be coupled to a drain contact 136 (FIG. 5-6) of the second semiconductor die 110. As shown, the drain contact 136 may, in some examples, be on an opposing side of the second semiconductor die 110 relative to the source contact 132 and the gate contact 134. In some examples, the third lead 130-3 may be coupled to the drain contact 136 using, for instance, one or more wire bond(s) (not shown). In this way, the third lead 130-3 of the second plurality of electrical leads 130 may be used to connect the drain of the MOSFET on the second semiconductor die 110 to one or more external connections.

The fourth lead 130-4 of the second plurality of electrical leads 130 may include an electrical connection pin. In some examples, the fourth lead 130-4 may be coupled to the additional contact 138 (FIG. 5- 6) of the second semiconductor die 110. In some examples, the fourth lead 130-4 may be coupled to the additional contact 138 using, for instance, one or more wire bonds 162. As noted above, the additional contact 138 of the second semiconductor die 110 may be a source-Kelvin contact, a sensor contact, and/or the like. In this way, the fourth lead 130-4 of the second plurality of electrical leads 130 may be used to connect the additional contact 128 of the MOSFET on the first semiconductor die 108 to one or more external connections.

It should be understood that the arrangement of the leads 130-1-130-4 of the second plurality of electrical leads 130 is for purposes of illustration and discussion. Those having ordinary skill in the art, using the disclosures provided herein, will understand that the leads 130-1-130-4 of the second plurality of electrical leads 130 may be rearranged, adjusted, etc. without deviating from the scope of the present disclosure.

In some examples, the first plurality of electrical leads 120 may have an inverse configuration relative to the second plurality of electrical leads 130. More particularly, in some examples, the first lead 120-1 and the second lead 120-2 of the first plurality of electrical leads 120 may extend from an opposing side of the housing 102 relative to the first lead 130-1 and the second lead 130-2 of the second plurality of electrical leads 130. For instance, as shown in FIG. 1-6, the first lead 120-1 and the second lead 120-2 of the first plurality of electrical leads 120 may extend in a generally perpendicular direction from the first minor side 106A of the housing 102, and the third lead 120-3 of the first plurality of electrical leads 120 may extend in a generally perpendicular direction from the second minor side 106B of the housing 102. In contrast, the first lead 130-1 and the second lead 130-2 of the second plurality of electrical leads 130 may extend in a generally perpendicular direction from the second minor side 106B of the housing 102, and the third lead 130-3 of the second plurality of electrical leads 130 may extend in a generally perpendicular direction from the first minor side 106A of the housing 102. In this way, the first plurality of electrical leads 120 may be rotated 180-degrees about the housing plane H (e.g., defined by major sides 104) relative to the second plurality of electrical leads 130.

The power semiconductor device package 100 may further include a creepage extension structure 140 in the housing 102. More particularly, as shown in FIG. 2-4, the creepage extension structure 140 may be on the second major side 104B of the housing 102 between the first semiconductor die 108 and the second semiconductor die 110. As noted above, the creepage extension structure 140 may be between the first semiconductor die 108 and the second semiconductor die 110 when viewed from a top plan view and/or a bottom plan view.

For instance, as shown in FIG. 2, the creepage extension structure 140 is between the first plurality of electrical leads 120 and the second plurality of electrical leads 130 along the housing plane H. That is, as shown, the first submount 112 may be spaced apart from the second submount 114 along the housing plane H, and the creepage extension structure 140 may be between the first submount 112 and the second submount 114 along the housing plane H. Hence, the creepage extension structure 140 may increase a creepage distance (e.g., shortest direct path along a surface between conductors at different voltage potentials) between the first plurality of electrical leads 120 and the second plurality of electrical leads 130. In some examples (such as that depicted in FIG. 2-4), the creepage extension structure 140 may extend across the entire surface of the second major side 104B (e.g., from the first minor side 106A to the second minor side 106B). Additionally and/or alternatively, in some examples, the creepage extension structure 140 may extend across only a portion of the surface of the second major side 104B. Furthermore, in some examples (such as that depicted in FIG. 2-4), the creepage extension structure 140 may be a rectangular creepage extension structure 140 having at least two sidewall segments 142. Although depicted as being a rectangular creepage extension feature in FIG. 2- 4, the creepage extension structure 140 may, in some examples, be a non-rectangular creepage extension feature having more than two sidewall segments.

As shown in FIG. 2-4, the creepage extension structure 140 may be and/or may define a trench in the second major surface 104B of the housing 102. For instance, as shown, the trench (creepage extension structure 140) may be defined between the first portion 102A (e.g., first semiconductor die 108, first plurality of electrical leads 120) and the second portion 102B (e.g., second semiconductor die 110, second plurality of electrical leads 130) of the housing 102. In some examples, the trench (creepage extension structure 140) may have a depth D in a range of about 0.25 microns to about 2 microns, such as a depth D in a range of about 0.5 microns to about 1 micron, such as a depth D of about 0.75 microns. In this manner, the creepage extension structure 140 may increase the shortest direct path (e.g., creepage distance) along the second major side 104B of the housing 102 between the first plurality of electrical leads 120 and the second plurality of electrical leads 130. Although depicted as defining a trench in the housing 102 in FIG. 2-4, the creepage extension structure 140 may, in some examples, define a step structure in the housing 102, a slit in the housing 102, and/or the like. Those having ordinary skill in the art, using the disclosures provided herein, will understand that the creepage extension structures of the present disclosure may have any suitable shape, structure, configuration, etc. without deviating from the scope of the present disclosure, such as any suitable shape, structure, configuration, etc. that serves to increase the shortest direct path along a surface between conductors at different voltage potentials.

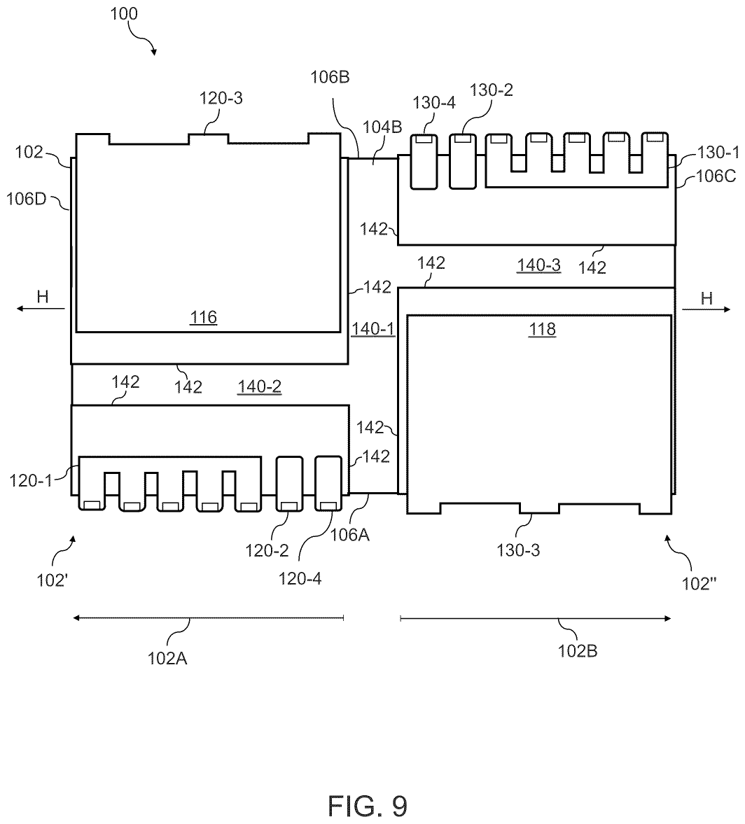

Variations and modifications may be made to the example power semiconductor device package 100 described herein without deviating from the scope of the present disclosure. For instance, the creepage extension structure 140 may, in some examples, be a non-rectangular creepage extension structure having more than two sidewall segments 142. By way of non-limiting illustrative example, FIG. 9 depicts a bottom plan view of the power semiconductor device package 100. As shown, in some examples, the creepage extension structure 140 may be a non-rectangular creepage extension structure having at least eight sidewall segments 142. More particularly, the creepage extension structure 140 may include a first creepage portion 140-1 between the first semiconductor die 108 (FIG. 5-6) and the second semiconductor die 110 (FIG. 5-6). That is, the first creepage portion 140-1 may be on the second major side 104B of the housing 102 between the first portion 102A and the second portion 102B of the housing 102. In some examples, at least a portion of the creepage extension structure 140, such as the first creepage portion 140-1, may be between the first submount 112 and the second submount 114 along the housing plane H. As shown, the first creepage portion 140-1 of the creepage extension structure 140 extends from the first minor side 106A of the housing 102 to the second minor side 106B of the housing 102.

Referring still to FIG. 9, in some examples, the creepage extension structure 140 may also include a second creepage portion 140-2. The second creepage portion 140-2 may be perpendicular to the first creepage portion 140-1 and may extend laterally from the first creepage portion 140-1 towards the first semiconductor die 108 (FIG. 5-6) (e.g., across the first portion 102A of the housing 102). More particularly, the second creepage portion 140-2 may extend laterally between the first creepage portion 140-1 and the first peripheral end 102′of the housing 102. That is, in some examples, the second creepage portion 140-2 may extend from the first creepage portion 140-1 to the fourth minor side 106D of the housing 102. Hence, the second creepage portion 140-2 of the creepage extension structure 140 provides an increased creepage distance between the first lead 120-1 and the third lead 120-3 of the first plurality of electrical leads 120.

Referring still to FIG. 9, in some examples, the creepage extension structure 140 may also include a third creepage portion 140-3. The third creepage portion 140-3 may be perpendicular to the first creepage portion 140-1 and may extend laterally from the first creepage portion 140-1 towards the second semiconductor die 110 (FIG. 5-6) (e.g., across the second portion 102B of the housing 102). More particularly, the third creepage portion 140-3 may extend laterally between the first creepage portion 140-1 and the second peripheral end 102″ of the housing 102 that is opposite the first peripheral end 102′. That is, in some examples, the third creepage portion 140-3 may extend from the first creepage portion 140-1 to the third minor side 106C of the housing 102. Hence, the third creepage portion 140-3 of the creepage extension structure 140 provides an increased creepage distance between the first lead 130-1 and the third lead 130-3 of the second plurality of electrical leads 130.

It should be understood that the power semiconductor device package 100 of FIG. 1-9 is depicted as having only one creepage extension structure 140 in the housing 102 for purposes of illustration and discussion. Those having ordinary skill in the art, using the disclosures provided herein, will understand that the power semiconductor device package 100 may include any number of creepage extension structures on any side of the housing 102 without deviating from the scope of the present disclosure. For instance, as will be discussed in greater detail below, in some examples, the power semiconductor device package 100 may further include a second creepage extension structure and/or a third creepage extension structure on the first major side 104A and/or the second major side 104B without deviating from the scope of the present disclosure.

As noted above, in some examples, power semiconductor device packages of the present disclosure may also be configured as top-side cooled power semiconductor device packages. By way of non-limiting example, FIG. 10-15 depict an example top-side cooled power semiconductor device package 200 according to example embodiments of the present disclosure. As will be discussed in greater detail below, the power semiconductor device package 200 is configured to dissipate heat through its top side and/or top surface. It should be understood that FIG. 10-15 are intended to represent structures for purposes of identification and description and are not intended to represent the structures to physical scale.

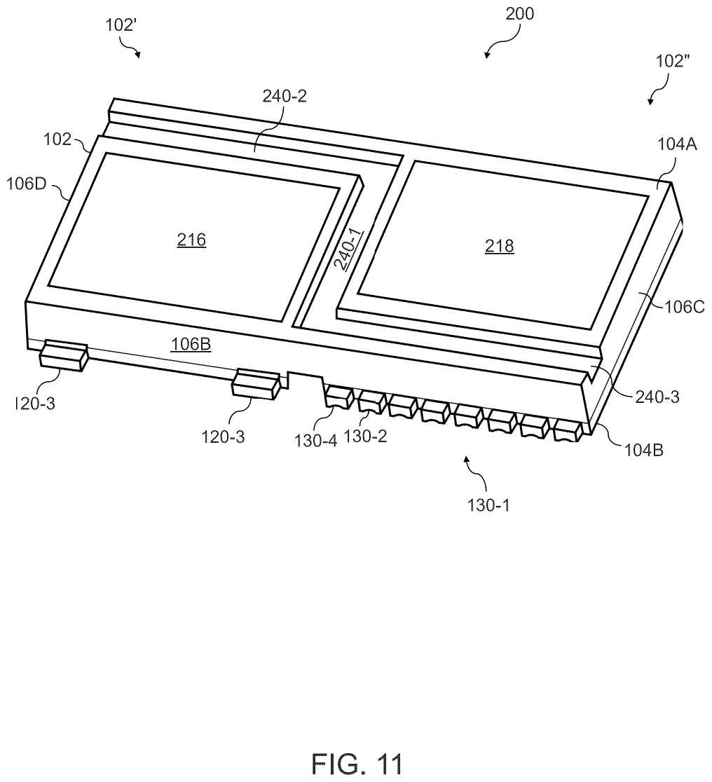

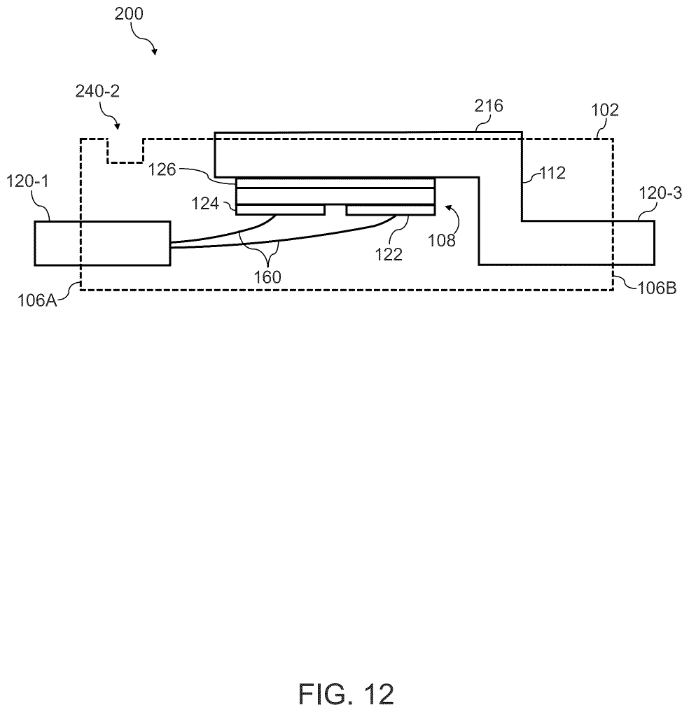

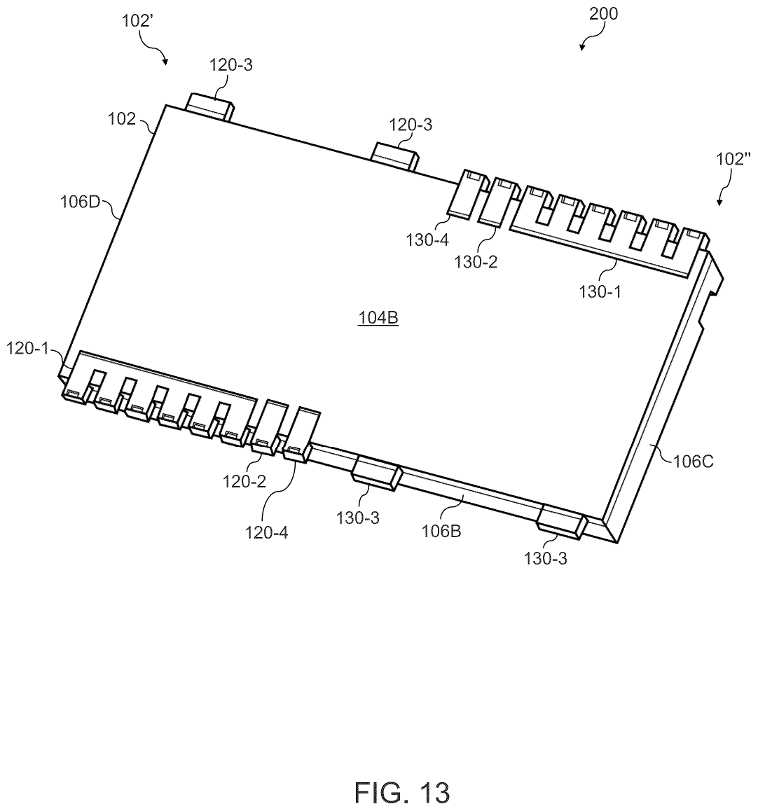

Referring now to FIG. 10-13, FIG. 10 depicts a top plan view of the power semiconductor device package 200, FIG. 11 depicts a top perspective view of the power semiconductor device package 200, FIG. 12 depicts a cross-sectional side view of the power semiconductor device package 200 taken along the line A-A (e.g., depicted in FIG. 10), and FIG. 13 depicts a bottom perspective view of the power semiconductor device package 200.

The power semiconductor device package 200 may be similar to any of the power semiconductor device packages described herein, such as the power semiconductor device package 100 (FIG. 1-9) and/or the like. For instance, the power semiconductor device package 200 may include the first semiconductor die 108 (FIG. 5-6) and the second semiconductor die 110 (FIG. 5-6) within the housing 102. As described above, the first semiconductor die 108 may be on the first submount 112 (FIG. 5-6), and the second semiconductor die 110 may be on the second submount 114 (FIG. 5-6). The power semiconductor device package 200 may further include the first plurality of electrical leads 120 (e.g., coupled to the first semiconductor die 108) and the second plurality of electrical leads 130 (e.g., coupled to the second semiconductor die 110).

However, in contrast to the power semiconductor device package 100 (FIG. 1-9), the power semiconductor device package 200 is configured to dissipate heat through the first major side 104A (e.g., top side) of the housing 102. More particularly, as shown, the power semiconductor device package 200 includes a first conductive structure 216 and a second conductive structure 218 that are at least partially exposed through the first major side 104A of the housing 102. With the exception of the major side on which they are located, the first conductive structure 216 and the second conductive structure 218 may be similar to the first conductive structure 116 (FIG. 1-9) and the second conductive structure 118 (FIG. 1-9), respectively. For instance, the first submount 112 (FIG. 5-6) may be and/or may include the first conductive structure 216, and the second submount 114 (FIG. 5-6) may be and/or may include the second conductive structure 218. Moreover, the first conductive structure 216 may be coupled to the drain contact 126 of the first semiconductor die 108 (FIG. 5-6), and the second conductive structure 218 may be coupled to the drain contact 136 of the second semiconductor die 110 (FIG. 5-6).

However, as shown in FIG. 10-13, the first conductive structure 216 and the second conductive structure 218 may be at least partially exposed through the first major side 104A of the housing 102 and, thus, may provide a heat dissipation path for the first semiconductor die 108 (FIG. 5-6) and the second semiconductor die 110 (FIG. 5-6) (respectively) through the first major side 104A of the housing 102. Hence, the first conductive structure 216 and the second conductive structure 218 may provide for top-side cooling of the power semiconductor device package 200. As an illustrative example, FIG. 13 depicts a cross-sectional side view of the power semiconductor device package 200 taken along the line A-A as depicted in FIG. 10. In the example of FIG. 13, the first submount 112 is a first lead frame, and the first lead frame is at least partially exposed through the first major side 104A of the housing 102. Although not depicted in FIG. 13, the second submount 114 may likewise be a lead frame (e.g., a second lead frame) and may be packaged in the housing 102 in a similar manner as the first lead frame (e.g., first submount 112) depicted in FIG. 13.

The power semiconductor device package 200 may further include a first creepage extension structure 240 in the housing 102. The first creepage extension structure 240 may be similar to any of the creepage extension structures described herein, such as the creepage extension structure 140 (FIG. 1-9). For instance, the first creepage extension structure 240 may be a non-rectangular creepage extension structure 240 and may define a trench in the housing 102. However, as shown in FIG. 10-13, the first creepage extension structure 240 may be on the first major side 104A of the housing 102 and may include at least six sidewall segments 242.

More particularly, as shown in FIG. 10-13, the first creepage extension structure 240 may include a first creepage portion 240-1 between the first semiconductor die 108 (FIG. 5-6, 12) and the second semiconductor die 110 (FIG. 5-6). That is, the first creepage portion 240-1 may be on the first major side 104A of the housing 102 and may be between the first portion 102A and the second portion 102B of the housing 102 when viewed from a top plan view and/or a bottom plan view, such as the top plan view depicted in FIG. 10. As shown, in some examples, the first creepage portion 240-1 may extend across a portion of the first major side 104A of the housing 102 between the first minor side 106A of the housing 102 and the second minor side 106B of the housing 102. In some examples, at least a portion of the first creepage extension structure 240, such as the first creepage portion 240-1, may be between the first submount 112 and the second submount 114 along the housing plane H. Additionally and/or alternatively, in other examples, the first creepage portion 240-1 of the first creepage extension structure 240 may extend across the entire surface of the first major side 104A (e.g., from the first minor side 106A of the housing 102 to the second minor side 106B of the housing 102).

The first creepage extension structure 240 may also include a second creepage portion 240-2. The second creepage portion 240-2 may be perpendicular to the first creepage portion 240-1 and may extend laterally from the first creepage portion 240-1 towards the first semiconductor die 108 (FIG. 5-6) (e.g., across the first portion 102A of the housing 102).

More particularly, the second creepage portion 240-2 may extend laterally between the first creepage portion 240-1 and the first peripheral end 102′of the housing 102. That is, in some examples, the second creepage portion 240-2 may extend from the first creepage portion 240-1 to the fourth minor side 106D of the housing 102. Hence, the second creepage portion 240-2 of the first creepage extension structure 240 may provide an increased creepage distance between the first lead 120-1 and the third lead 120-3 of the first plurality of electrical leads 120.

The first creepage extension structure 240 may also include a third creepage portion 240-3. The third creepage portion 240-3 may be perpendicular to the first creepage portion 240-1 and may extend laterally from the first creepage portion 240-1 towards the second semiconductor die 110 (FIG. 5-6) (e.g., across the second portion 102B of the housing 102). More particularly, the third creepage portion 240-3 may extend laterally between the first creepage portion 240-1 and the second peripheral end 102″ of the housing 102 that is opposite the first peripheral end 102′. That is, in some examples, the third creepage portion 240-3 may extend from the first creepage portion 240-1 to the third minor side 106C of the housing 102.

Hence, the third creepage portion 240-3 of the first creepage extension structure 240 may provide an increased creepage distance between the first lead 130-1 and the third lead 130-3 of the second plurality of electrical leads 130.

Although depicted as a non-rectangular creepage extension structure in FIG. 10-13, the first creepage extension structure 240 may, in other examples, be a rectangular creepage extension structure 240 and/or may define a step structure in the housing 102 without deviating from the scope of the present disclosure. For instance, by way of non-limiting example, the first creepage extension structure 240 may have an arrangement and/or configuration similar to the creepage extension structure 140 described above with reference to FIG. 1-9.

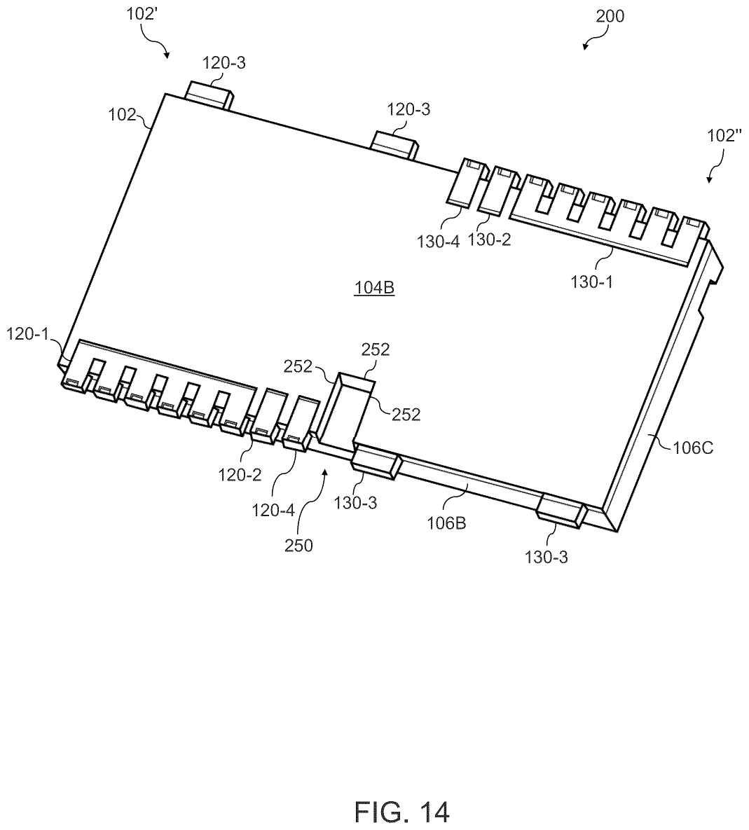

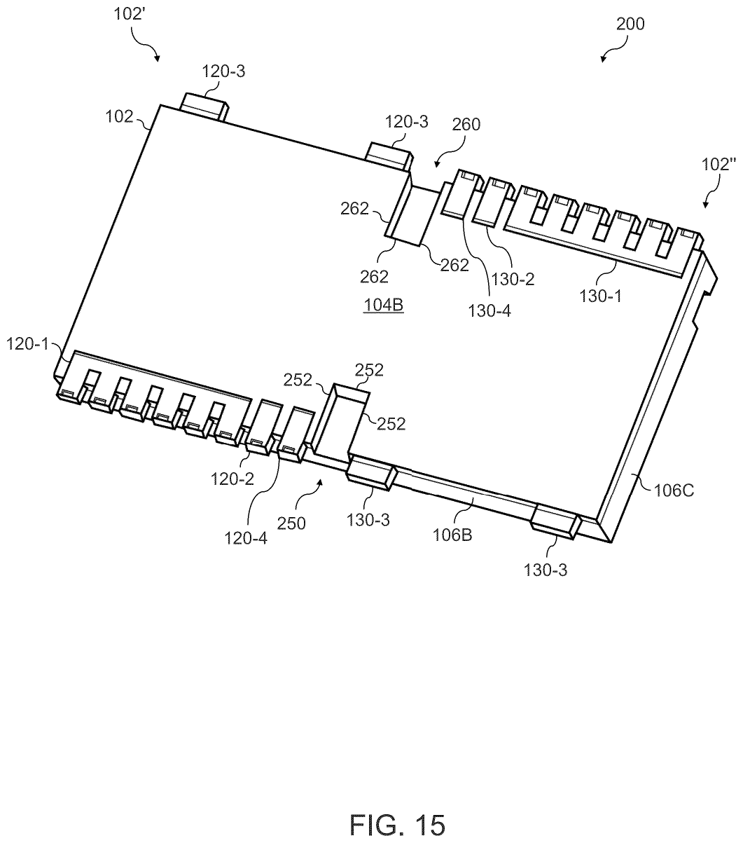

Variations and modifications may be made to the example power semiconductor device package 200 described herein without deviating from the scope of the present disclosure. For instance, the power semiconductor device package 200 may, in some examples, include one or more additional creepage extension features on a major side 104 of the housing 102 opposite the first creepage extension structure 240. For instance, FIG. 14-15 depict the example power semiconductor device package 200 discussed above with reference to FIG. 10-13 with additional creepage extension feature(s) on the second major side 104B of the housing 102 (e.g., the major side 104 of the housing 102 opposite the first creepage extension structure 240).

As one non-limiting illustrative example, FIG. 14 depicts a bottom perspective view of the power semiconductor device package 200. As shown, in some examples, the power semiconductor device package 200 may further include a second creepage extension structure 250 in the housing 102 opposite the first creepage extension structure 240 (e.g., on the second major side 104B of the housing 102). In some examples, such as that depicted in FIG. 14, the second creepage extension structure 250 may be on the second major side 104B of the housing 102 between the drain contact 126 (FIG. 5-6) of the first semiconductor die 108 (FIG. 5-6) and the source contact 132 (FIG. 5-6) of the second semiconductor die 110 (FIG. 5-6). That is, the second creepage extension structure 250 may be on the second major side 104B of the housing 102 and may be between the third lead 120-3 of the first plurality of electrical leads 120 and the first lead 130-1 of the second plurality of electrical leads 130. Hence, the second creepage extension structure 250 may be between the first submount 112 and the second submount 114 along the housing plane H. In this way, the second creepage extension structure 250 may provide an increased creepage distance between the first plurality of electrical leads 120 and the second plurality of electrical leads 130.

As another non-limiting illustrative example, FIG. 15 depicts a bottom perspective view of the power semiconductor device package 200. As shown, in some examples, the power semiconductor device package 200 may further include a third creepage extension structure 260 in the housing 102 opposite the first creepage extension structure 240 (e.g., on the second major side 104B of the housing 102). Put differently, the third creepage extension structure 260 may, in some examples, be on a same major side 104 of the housing 102 as the second creepage extension structure 250. In some examples, such as that depicted in FIG. 15, the third creepage extension structure 260 may be on the second major side 104B of the housing 102 and may be between the source contact 122 (FIG. 5-6) of the first semiconductor die 108 (FIG. 5-6) and the drain contact 136 (FIG. 5-6) of the second semiconductor die 110 (FIG. 5-6). That is, the third creepage extension structure 260 may be on the second major side 104B of the housing 102 between the first lead 120-1 of the first plurality of electrical leads 120 and the third lead 130-3 of the second plurality of electrical leads 130. Hence, the third creepage extension structure 260 may be between the first submount 112 and the second submount 114 along the housing plane H. In this way, the third creepage extension structure 260 may provide an increased creepage distance between the first plurality of electrical leads 120 and the second plurality of electrical leads 130.

Referring now to FIG. 14-15, the second creepage extension structure 250 and the third creepage extension structure 260 may have any suitable shape, arrangement, and/or configuration without deviating from the scope of the present disclosure. For instance, in the examples depicted in FIG. 14-15, the second creepage extension structure 250 is a rectangular creepage cutout in the housing 102 having at least three sidewall segments 252; likewise, the third creepage extension structure 260 is a rectangular creepage cutout in the housing 102 having at least three sidewall segments 262. Hence, in some examples, the second creepage extension structure 250 may have a same shape as the third creepage extension structure 260. In other examples, the second creepage extension structure 250 may have a different shape than the third creepage extension structure 260.

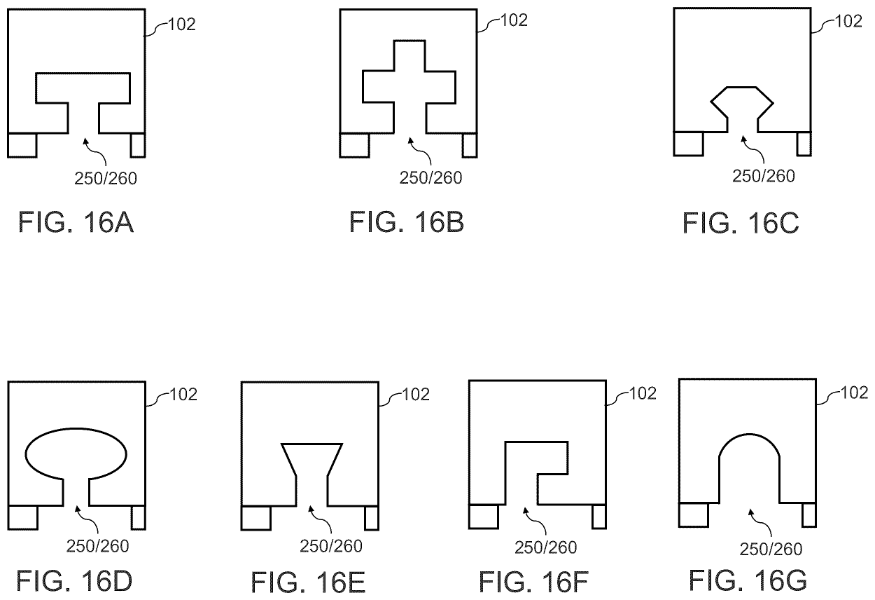

Additionally and/or alternatively, in some examples, the second creepage extension structure 250 and the third creepage extension structure 260 may be non-rectangular creepage cutouts. Non-rectangular creepage cutouts are discussed in greater detail below with reference to FIG. 16A-16G. It should be understood that the second creepage extension structure 250 and the third creepage extension structure 260 are depicted as creepage cutouts for purposes of illustration and discussion. Those having ordinary skill in the art, using the disclosures provided herein, will understand that the second creepage extension structure 250 and the third creepage extension structure 260 may have any suitable shape, configuration, arrangement, and/or the like without deviating from the scope of the present disclosure. For instance, the second creepage extension structure 250 and the third creepage extension structure 260 may have a similar shape, configuration, and/or arrangement as any of the creepage extension structures described herein, such as the creepage extension structure 140, the first creepage extension structure 240, and/or the like.

Variations and modifications may be made to the example power semiconductor device package 200 described herein without deviating from the scope of the present disclosure. For instance, in some examples, the second creepage extension structure 250 and/or the third creepage extension structure 260 may be non-rectangular creepage cutouts. By way of non-limiting illustrative examples, FIG. 16A-16G depict various example non-rectangular creepage extension structures (e.g., creepage cutouts) according to example embodiments of the present disclosure. It should be understood that FIG. 16A-16G are intended to represent structures for purposes of identification and description and are not intended to represent the structures to physical scale.

As noted above, in addition to the other shapes, configurations, and/or arrangements of the other creepage extension structures described herein, the second creepage extension structure 250 and the third creepage extension structure 260 may be non-rectangular creepage cutouts. By way of non-limiting illustrative example, the second creepage extension structure 250 and/or the third creepage extension structure 260 may be any of the non-rectangular creepage cutouts depicted in FIG. 16A-16G, such as a T-shaped creepage cutout (FIG. 16A), a cross-shaped creepage cutout (FIG. 16B), a hexagonal creepage cutout (FIG. 16C), a circular creepage cutout (FIG. 16D), a triangular creepage cutout (FIG. 16E), an L-shaped creepage cutout (FIG. 16F), a curved creepage cutout (FIG. 16G), and/or the like.

It should be understood that the non-rectangular creepage cutouts depicted in FIG. 16A-16G are for purposes of illustration and discussion. Those having ordinary skill in the art, using the disclosures provided herein, will understand that any suitable rectangular and/or non-rectangular creepage cutout, as well as any of the rectangular and/or non-rectangular creepage extension structures described herein (e.g., FIG. 1-15), may be used without deviating from the scope of the present disclosure.

As noted above, in some examples, power semiconductor device packages of the present disclosure may also be configured as dual-side cooled power semiconductor device packages. By way of non-limiting examples, FIG. 17-19 depict an example dual-side cooled power semiconductor device package 300 according to example embodiments of the present disclosure. As will be discussed in greater detail below, the power semiconductor device package 300 is configured to dissipate heat through both its bottom side and/or bottom surface and its top side and/or top surface. It should be understood that FIG. 17-19 are intended to represent structures for purposes of identification and description and are not intended to represent the structures to physical scale.

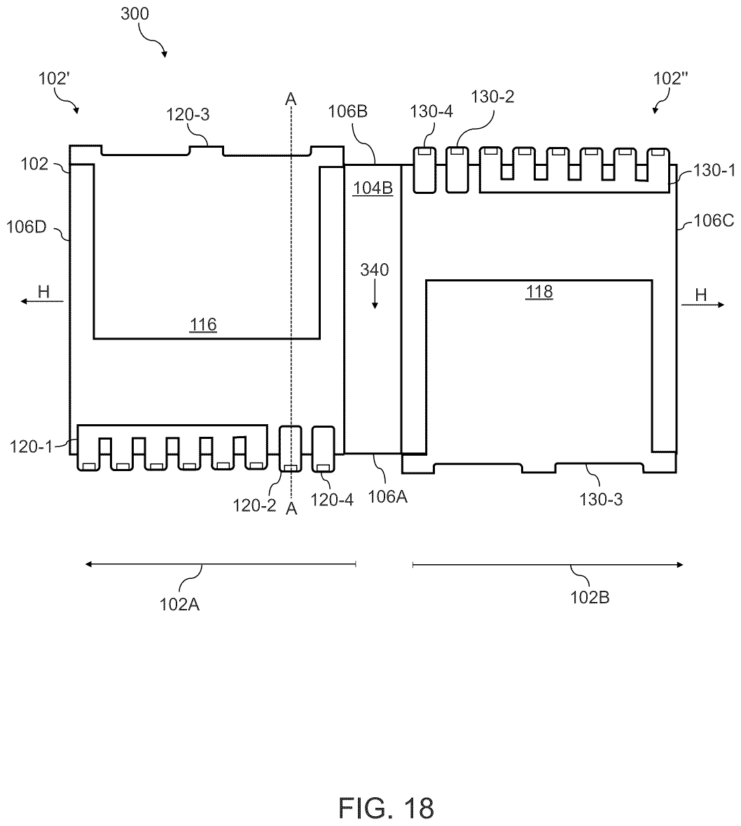

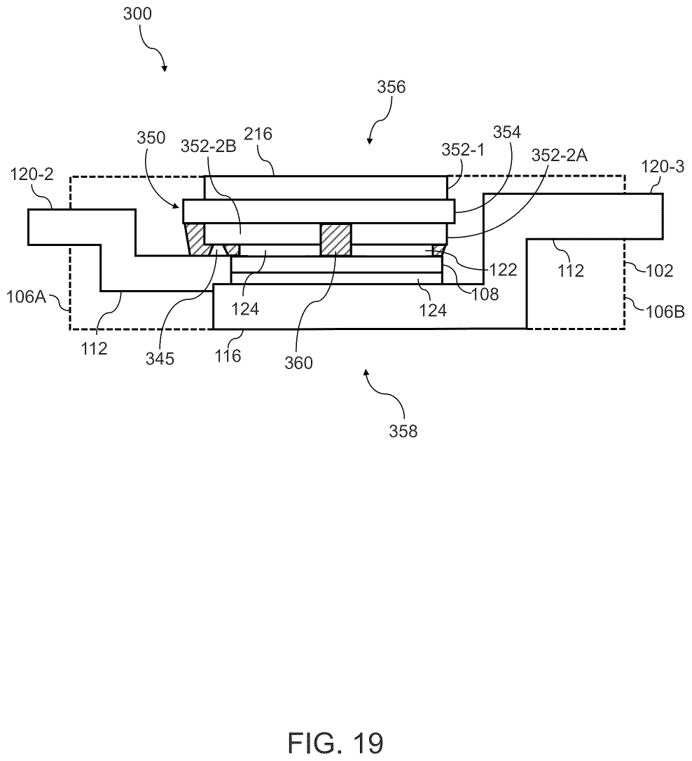

More particularly, FIG. 17 depicts a top plan view of the power semiconductor device package 300, FIG. 18 depicts a bottom plan view of the power semiconductor device package 300, and FIG. 19 depicts a cross-sectional side view of the power semiconductor device package 300 taken along the line A-A (e.g., depicted in FIG. 17-18). The power semiconductor device package 300 may be similar to any of the power semiconductor device packages described herein, such as the power semiconductor device package 100 (FIG. 1-9), the power semiconductor device package 200 (FIG. 10-15), and/or the like. For instance, the power semiconductor device package 300 may include the first semiconductor die 108 (FIG. 5-6) and the second semiconductor die 110 (FIG. 5-6) within the housing 102. As described above, the first semiconductor die 108 may be on the first submount 112 (FIG. 5-6), and the second semiconductor die 110 may be on the second submount 114 (FIG. 5-6). The power semiconductor device package 300 may further include the first plurality of electrical leads 120 (e.g., coupled to the first semiconductor die 108) and the second plurality of electrical leads 130 (e.g., coupled to the second semiconductor die 110).

However, in contrast to the power semiconductor device package 100 (FIG. 1-9) and/or the power semiconductor device package 200 (FIG. 10-15), the power semiconductor device package 300 is configured to dissipate heat through both the first major side 104A (e.g., top side) of the housing 102 and the second major side 104B (e.g., bottom side) of the housing 102.

More particularly, as shown in FIG. 17, the power semiconductor device package 300 includes the first conductive structure 216 and the second conductive structure 218 at least partially exposed through the first major side 104A of the housing 102. The first conductive structure 216 and the second conductive structure 218 are described in greater detail above with reference to FIG. 10-15. Like the power semiconductor device package 200 described above (e.g., FIG. 10-15), the first conductive structure 216 and the second conductive structure 218 provide a first heat dissipation path for the first semiconductor die 108 (FIG. 5-6) and the second semiconductor die 110 (FIG. 5-6) (respectively), which is through the first major side 104A of the power semiconductor device package 300. Likewise, as shown in FIG. 18, the power semiconductor device package 300 further includes a third conductive structure (e.g., the first conductive structure 116) and a fourth conductive structure (e.g., the second conductive structure 118) at least partially exposed through the second major side 104B of the housing 102. The first conductive structure 116 and the second conductive structure 118 are described in greater detail above with reference to FIG. 1-9. Like the power semiconductor device package 100 described above (e.g., FIG. 1-9), the first conductive structure 116 and the second conductive structure 118 provide a second heat dissipation path for the first semiconductor die 108 (FIG. 5-6) and the second semiconductor die 110 (FIG. 5-6) (respectively), which is through the second major side 104B of the power semiconductor device package 300.

Put differently, the first conductive structure 216 and the second conductive structure 218 on (e.g., exposed through) the first major side 104A (e.g., top side) of the housing 102 provide for top-side cooling of the power semiconductor device package 300.

Similarly, the first conductive structure 116 and the second conductive structure 118 on (e.g., exposed through) the second major side 104B (e.g., bottom side) of the housing 102 provide for bottom-side cooling of the power semiconductor device package 300. As such, the power semiconductor device package 300 may have at least one heat dissipation path through each of the major sides 104 of the housing 102. Hence, in some examples, the power semiconductor device package 300 may be configured for dual-side cooling.

As an illustrative example, FIG. 19 depicts a cross-sectional side view of the power semiconductor device package 300 taken along the line A-A as depicted in FIG. 17-18. It should be understood that FIG. 19 depicts only a portion of the first portion 102A of the power semiconductor device package 300 for purposes of illustration and discussion. Those having ordinary skill in the art, using the disclosures provided herein, will understand that the second portion 102B of the power semiconductor device package 300 may have a similar and/or identical arrangement as that depicted in FIG. 19.

More particularly, as shown in FIG. 19, the first semiconductor die 108 may be on the first submount 112 which, in the example of FIG. 19, is a first lead frame. The first submount 112 may include the first conductive structure 116 which, as shown, is at least partially exposed through the second major side 104B of the housing. The power semiconductor device package 300 further includes an additional submount, such as a power substrate 350, on an opposing side of the first semiconductor die 108 relative to the first submount 112. The power substrate 350 may be any suitable power substrate, such as a direct bonded copper (DBC) substrate, an active metal brazed (AMB) substrate, and/or the like.

As shown, the power substrate 350 may include a plurality of metal layers 352 and an insulating layer 354 between the metal layers 352. In some examples, such as that depicted in FIG. 19, the first conductive structure 216 may be and/or may include one of the plurality of metal layers 352, such as metal layer 352-1 (e.g., thermal pad). Hence, in some examples, the first conductive structure 216 may be on the insulating layer 354. The insulating layer 354 may be formed from an insulating material, such as a ceramic material and/or other insulating materials. The insulating layer 354 may have another of the plurality of metal layers 352, such as metal layer 352-2, on a surface opposite metal layer 352-1 (e.g., conductive structure 216). As such, the insulating layer 354 may provide electrical isolation between the first plurality of electrical leads 120 and the metal layer 352-1 (e.g., conductive structure 216).

In some examples, the metal layer 352-2 may be and/or may include one or more conductive pads that are coupled to one or more contacts of the first semiconductor die 108. For instance, as shown in FIG. 19, the source contact 122 of the first semiconductor die 108 may be coupled to metal layer 352-2A, and the gate contact 124 of the first semiconductor die 108 may be coupled to metal layer 352-2B. The source contact 122 and the gate contact 124 may be directly coupled to the power substrate 350 with or without a die-attach material. In some examples, the metal layer 352-2 may be coupled to one or more of the first plurality of electrical leads 120 to facilitate connection of the power semiconductor device package 300 to an external component, such as one or more circuits. For instance, as shown in FIG. 19, the metal layer 352-2B may be coupled to the second lead 120-2 of the first plurality of electrical leads 120 using an interconnection 345. The interconnection 345 may include, for instance, an attach material (e.g., solder, paste, sintered material, etc.). Although not depicted in FIG. 19, the metal layer 352-2A may be similarly coupled to the first lead 120-1 of the first plurality of electrical leads 120 using an interconnection (not shown).

The power semiconductor device package 300 may further include an insulating gap layer 360 on the first semiconductor die 108. For instance, the insulating gap layer 360 may be on the surface of the semiconductor die 108 having the source contact 122, the gate contact 124, and the additional contact 128 (not shown). In some examples, the insulating gap layer 360 may extend between the first semiconductor die 108 and the first submount 112, such that the insulating gap layer 360 fills any gaps between the first semiconductor die 108 and the first submount 112. The insulating gap layer 360 may not extend to and/or may not be on the surface of the first semiconductor die 108 that includes the drain contact 126. In some examples, the insulating gap layer 360 includes an underfill material, such as a polymer-based material (e.g., epoxy polymer material) and/or the like. Additionally and/or alternatively, in some examples, the insulating gap layer 360 includes a filler or other component, such as a flowing agent, an adhesive agent, and/or the like.

As shown in FIG. 19, the metal layer 352-1 of the power substrate 350 (e.g., conductive structure 216) may be at least partially exposed through the housing 102, such as through an opening 356 in the first major side 104A of the housing 102. As such, the metal layer 352-1 of the power substrate 350 (e.g., conductive structure 216) may provide a thermally conductive cooling path (e.g., heat dissipation path) for cooling of the first semiconductor die 108 through the first major side 104A of the housing 102. The metal layer 352-1 of the power substrate 350 (e.g., conductive structure 216) may be coupled to an external heat sink and/or may provide a thermally conductive path to an ambient environment of the power semiconductor device package 300. Similarly, the first submount 112 (e.g., conductive structure 116) may also be at least partially exposed through the housing 102, such as through an opening 358 in the second major side 104B of the housing 102. As such, the first submount 112 (e.g., conductive structure 116) may provide a thermally conductive cooling path (e.g., heat dissipation path) for cooling of the first semiconductor die 108 through the second major side 104B of the housing 102. The first submount 112 (e.g., conductive structure 116) may be coupled to an external heat sink and/or may provide a thermally conductive cooling path to the ambient environment of the power semiconductor device package 300.

Referring again to FIG. 17-19, the power semiconductor device package 300 may further include at least one creepage extension structure in the housing 102. For instance, as shown in FIG. 18, the power semiconductor device package 300 may include a creepage extension structure 340 on the second major side 104B of the housing 102 (e.g., between the first semiconductor die 108 (FIG. 5-6) and the second semiconductor die 110 (FIG. 5-6)). In some examples, at least a portion of the creepage extension structure 340 may be between the first submount 112 and the second submount 114 along the housing plane H. It should be understood that the creepage extension structure 340 depicted in FIG. 18 is for purposes of illustration and discussion. Those having ordinary skill in the art, using the disclosures provided herein, will understand that the power semiconductor device package 300 may include any suitable creepage extension structure, such as any of the creepage extension structures and/or creepage cutouts described herein (e.g., creepage extension structure 140, first creepage extension structure 240, second creepage extension structure 250, third creepage extension structure 260, and/or the like), without deviating from the scope of the present disclosure.

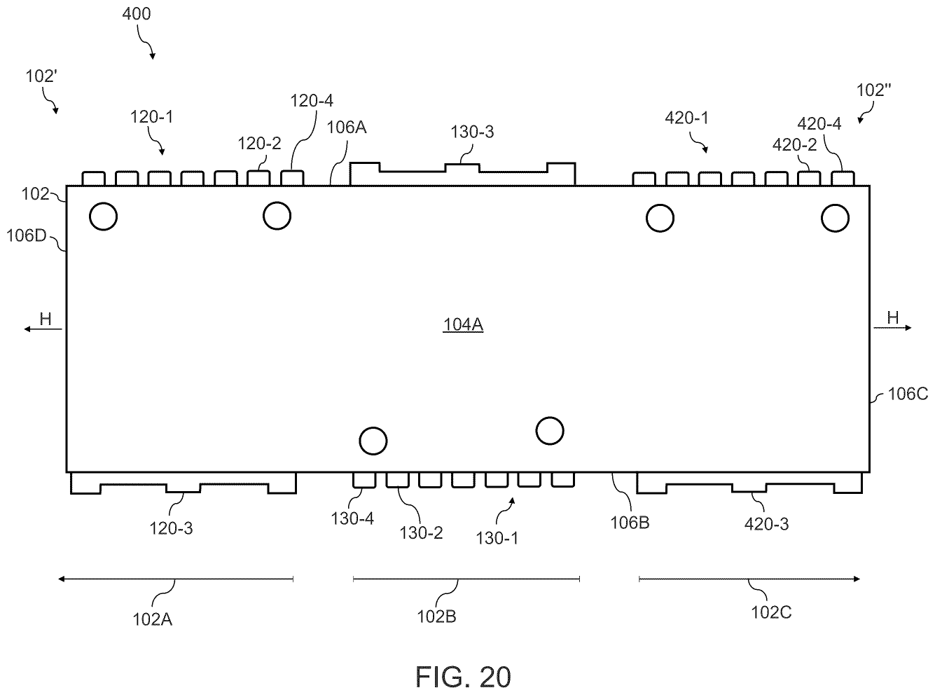

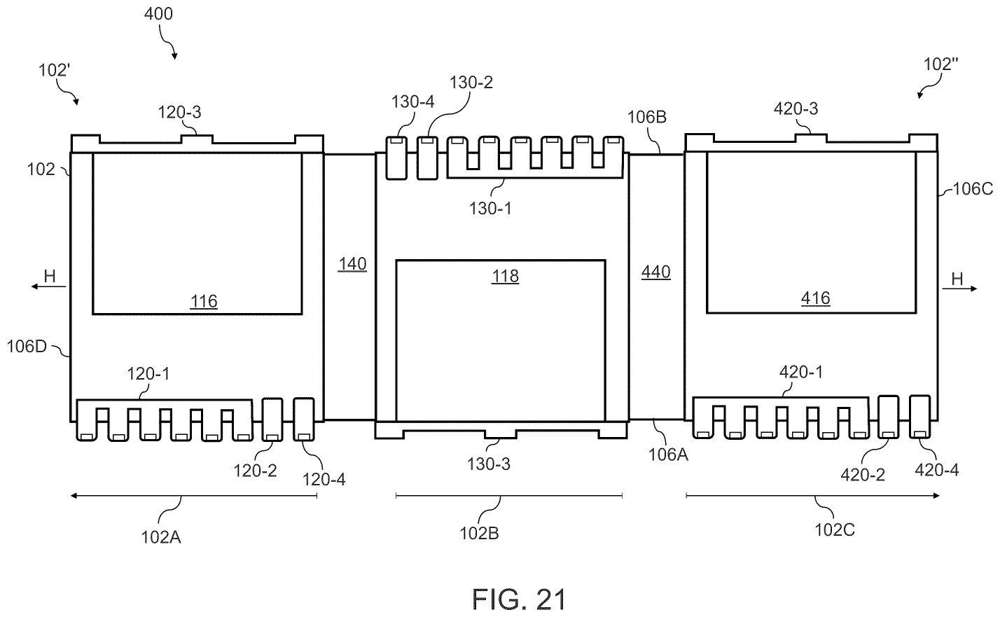

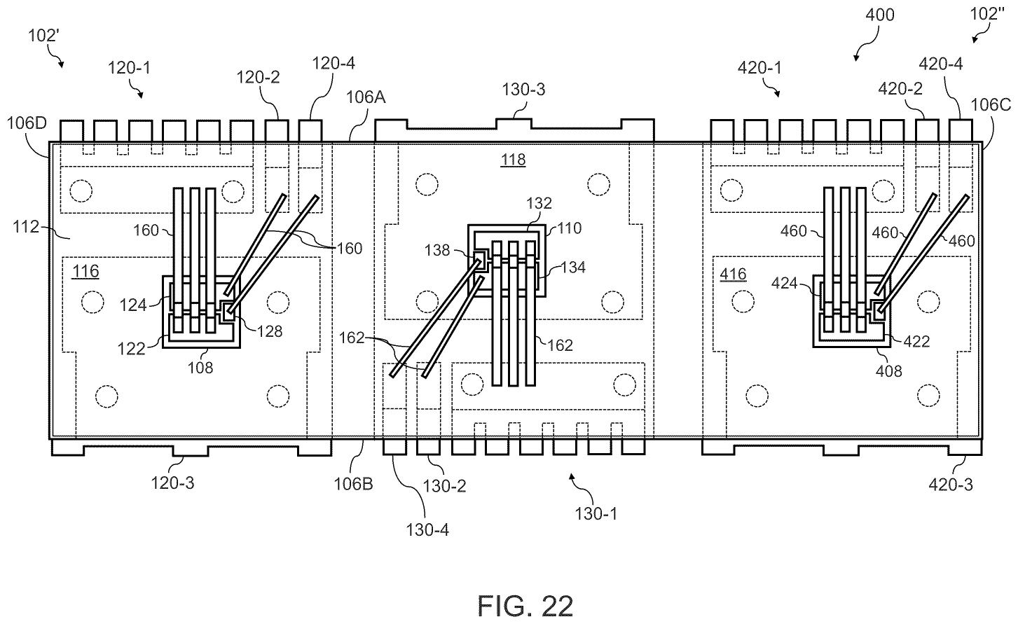

As noted above, in some examples, example power semiconductor device packages of the present disclosure may include more than two semiconductor within the housing 102. By way of non-limiting illustrative example, FIG. 20-22 depict an example power semiconductor device package 400 according to example embodiments of the present disclosure. More particularly, FIG. 20 depicts a top plan view of the power semiconductor device package 400, FIG. 21 depicts a bottom plan view of the power semiconductor device package 400; and FIG. 22 depicts a bottom wireframe view of the power semiconductor device package 400. It should be understood that FIG. 20-22 are intended to represent structures for purposes of identification and description and are not intended to represent the structures to physical scale.

The power semiconductor device package 400 may be similar to any of the power semiconductor device packages described herein, such as the power semiconductor device package 100 (FIG. 1-9), the power semiconductor device package 200 (FIG. 10-15), the power semiconductor device package 300 (FIG. 17-19), and/or the like. However, for ease of illustration and discussion, the power semiconductor device package 400 is depicted in FIG. 20-22 as a three-die variation of the power semiconductor device package 100. Put differently, although depicted and described as a top-side cooled power semiconductor device package (e.g., similar to the power semiconductor device package 100 (FIG. 1-9)), the power semiconductor device package 400 may likewise be a bottom-side cooled power semiconductor device package (e.g., similar to the power semiconductor device package 200 (FIG. 10-15)) and/or a dual-side cooled power semiconductor device package (e.g., similar to the power semiconductor device package 300 (FIG. 17-19)) without deviating from the scope of the present disclosure.

Referring to FIG. 20-22, the power semiconductor device package 400 may have a similar configuration as the power semiconductor device package 100 described above with reference to FIG. 1-9. For instance, the power semiconductor device package 400 may include the first semiconductor die 108 (FIG. 22) and the second semiconductor die 110 (FIG. 22) within the housing 102. As described above, the first semiconductor die 108 may be on the first submount 112 (FIG. 22), which may be and/or may include the first conductive structure 116; likewise, the second semiconductor die 110 may be on the second submount 114 (FIG. 22), which may be and/or may include the second conductive structure 118. The power semiconductor device package 400 may further include the first plurality of electrical leads 120 (e.g., coupled to the first semiconductor die 108) and the second plurality of electrical leads 130 (e.g., coupled to the second semiconductor die 110). The power semiconductor device package 400 may further include a creepage extension structure in the housing 102, such as the creepage extension structure 140. Those having ordinary skill in the art, using the disclosures provided herein, will understand that the power semiconductor device package 400 may include any of the creepage extension features described herein between the first portion 102A of the housing 102 and the second portion 102B of the housing 102.

As noted above, the power semiconductor device package 400 may be a three-die variation of the example power semiconductor device packages described above with reference to FIG. 1-18. Thus, in addition to the first semiconductor die 108 and the second semiconductor die 110, the power semiconductor device package 400 may further include a third semiconductor die 408 (e.g., defining a third portion 102C of the housing 102). The third semiconductor die 408 may be similar to the first semiconductor die 108 and the second semiconductor die 110, the details of which are described in greater detail above with reference to FIG. 1-9. It should be understood that example power semiconductor device packages of the present disclosure may, in some examples, include more than three semiconductor die without deviating from the scope of the present disclosure.

As shown in FIG. 22, the first semiconductor die 108, the second semiconductor die 110, and the third semiconductor die 408 may be arranged within the housing 102. Furthermore, like the first semiconductor die 108 and the second semiconductor die 110, the third semiconductor die 408 may be mounted on a mounting substrate, such as a third submount 412 (e.g., conductive lead frame). The third submount 412 may be similar to the first submount 112 and the second submount 114, the details of which are described in greater detail above with reference to FIG. 1-9. For instance, in some examples, at least a portion of the third submount 412 may be at least partially exposed through a major side of the housing 102.

In some examples, the third semiconductor die 408 may include a wide bandgap semiconductor material, such as silicon carbide (SiC), a Group-III nitride (e.g., gallium nitride (GaN)), and/or the like. Furthermore, the third semiconductor die 408 may include one or more semiconductor devices, such as metal-oxide-semiconductor field-effect transistor (MOSFET) devices, Schottky diodes, and/or other devices. For instance, as shown in FIG. 22, the third semiconductor die 408 may include silicon carbide-based MOSFET(s). In such examples, the third semiconductor die 408 may include a source contact 422, a gate contact 424, and a drain contact 426. In some examples, the third semiconductor die 408 may further include an additional contact 428, such as a source-Kelvin contact, a sensor contact, and/or the like.

Furthermore, as shown in FIG. 22, the third semiconductor die 408 may be electrically isolated from the first semiconductor die 108 and the second semiconductor die 110. Additionally and/or alternatively, in other examples, the power semiconductor device package 400 may include one or more die-to-die interfaces coupling the third semiconductor die 408 to one, or both, of the first semiconductor die 108 and the second semiconductor die 110.

Although described herein as including silicon carbide-based MOSFET(s), those having ordinary skill in the art, using the disclosures provided herein, will understand that the third semiconductor die 408 may include other power semiconductor devices without deviating from the scope of the present disclosure, such as diodes (e.g., Schottky diodes, PiN diodes, etc.), insulated gate bipolar transistors, high electron mobility transistors (HEMTs), and/or other devices. For instance, in some implementations, the third semiconductor die 408 may include a silicon-carbide based Schottky diode. Additionally and/or alternatively, in some implementations, the third semiconductor die 408 may include a Group-III nitride-based HEMT.

Referring again to FIG. 20-22, the power semiconductor device package 400 may further include a third conductive structure 416. More particularly, the third submount 412 may be and/or may include the third conductive structure 416. In some examples, the third submount 412 may be part of a third power substrate (e.g., power substrate 650 (FIG. 25A)), such as a third DBC substrate, a third AMB substrate, and/or the like. Additionally and/or alternatively, in some examples, the third submount 412 may be a third lead frame. Furthermore, in some examples, the third conductive structure 416 may be coupled to the drain contact 426 of the third semiconductor die 408. As such, like the first conductive structure 116 and the second conductive structure 118, the third conductive structure 416 may provide a heat dissipation path for the third semiconductor die 408 through the second major side 104B of the housing 102. In this way, as noted above, the power semiconductor device package 400 may be a top-side cooled power semiconductor device package 400.

The power semiconductor device package 400 may further include a third plurality of electrical leads 420 extending from the third portion 102C of the housing 102. As shown, the third plurality of electrical leads 420 may be partially encapsulated by the housing 102 such that a portion of each of the third plurality of electrical leads 420 is exposed through the third portion 102C of the housing 102. The third plurality of electrical leads 420 may be coupled to the third semiconductor die 408 and may have the form of electrical connection pins, such as surface mount type (SMT) connection structures. It should be understood that, although depicted as a plurality of leadless SMT connection structures, the third plurality of electrical leads 420 may have any suitable electrical connection pin, such as extended leads (FIG. 26A), Gull-wing pins (FIG. 26B), and/or the like.

In the example of the third semiconductor die 408 including a silicon carbide-based MOSFET, the third plurality of electrical leads 420 may include at least one first lead 420-1, at least one second lead 420-2, and at least one third lead 420-3. In some examples, the third plurality of electrical leads 420 may further include one or more additional leads, such as one or more fourth leads 420-4. Those having ordinary skill in the art, using the disclosures provided herein, will understand that the third plurality of electrical leads 420 may include more, or fewer, electrical leads without deviating from the scope of the present disclosure.

More particularly, the first lead 420-1 of the third plurality of electrical leads 420 may include an electrical connection pin. The first lead 420-1 may be coupled to the source contact 422 (FIG. 22) of the third semiconductor die 408. In some examples, the first lead 420-1 may be coupled to the source contact 422 using, for instance, one or more wire bonds 460. In this way, the first lead 420-1 of the third plurality of electrical leads 420 may be used to connect the source of the MOSFET on the third semiconductor die 408 to one or more external connections.

The second lead 420-2 of the third plurality of electrical leads 420 may include an electrical connection pin. The second lead 420-2 may be coupled to the gate contact 424 (FIG. 22) of the third semiconductor die 408. In some examples, the second lead 420-2 may be coupled to the gate contact 424 using, for instance, one or more wire bonds 460. In this way, the second lead 420-2 of the third plurality of electrical leads 420 may be used to connect the gate of the MOSFET on the third semiconductor die 408 to one or more external connections.

The third lead 420-3 of the third plurality of electrical leads 420 may include an electrical connection pin. The third lead 420-3 may be coupled to the drain contact 426 (FIG. 22) of the third semiconductor die 408. As shown, the drain contact 426 may, in some examples, be on an opposing side of the third semiconductor die 408 relative to the source contact 422 and the gate contact 424 In some examples, the third lead 420-3 may be coupled to the drain contact 426 using, for instance, one or more wire bond(s) (not shown). In this way, the third lead 420-3 of the third plurality of electrical leads 420 may be used to connect the drain of the MOSFET on the third semiconductor die 408 to one or more external connections.

The fourth lead 420-4 of the third plurality of electrical leads 420 may include an electrical connection pin. In some examples, the fourth lead 420-4 may be coupled to the additional contact 428 (FIG. 22) of the third semiconductor die 408. In some examples, the fourth lead 420-4 may be coupled to the additional contact 428 using, for instance, one or more wire bonds 460. As noted above, the additional contact 428 of the third semiconductor die 408 may be a source-Kelvin contact, a sensor contact, and/or the like. In this way, the fourth lead 420-4 of the third plurality of electrical leads 420 may be used to connect the additional contact 428 of the MOSFET on the third semiconductor die 408 to one or more external connections.

It should be understood that the arrangement of the leads 420-1-420-4 of the third plurality of electrical leads 420 is for purposes of illustration and discussion. Those having ordinary skill in the art, using the disclosures provided herein, will understand that the leads 420-1-420-4 of the third plurality of electrical leads 420 may be rearranged, adjusted, etc. without deviating from the scope of the present disclosure.

In some examples, the third plurality of electrical leads 420 may have a similar configuration relative to the first plurality of electrical leads 120. Thus, in some examples, the third plurality of electrical leads 420 may have an inverse configuration relative to the second plurality of electrical leads 130. More particularly, in some examples, the first lead 420-1 and the second lead 420-2 of the third plurality of electrical leads 420 may extend from an opposing side of the housing 102 relative to the first lead 130-1 and the second lead 130-2 of the second plurality of electrical leads 130. Similarly, the first lead 420-1 and the second lead 420-2 of the third plurality of electrical leads 420 may extend from the same side of the housing 102 relative to the first lead 120-1 and the second lead 120-2 of the first plurality of electrical leads 120. For instance, as shown in FIG. 20-22, the first lead 420-1 and the second lead 420-2 of the third plurality of electrical leads 420 may extend in a generally perpendicular direction from the first minor side 106A of the housing 102, and the third lead 420-3 of the third plurality of electrical leads 420 may extend in a generally perpendicular direction from the second minor side 106B of the housing 102. In this way, the third plurality of electrical leads 420 may be rotated 180-degrees about the housing plane H (e.g., defined by major sides 104) relative to the second plurality of electrical leads 130.

Referring still to FIG. 20-22, the power semiconductor device package 400 may further include a second creepage extension structure in the housing 102, such as the second creepage extension structure 440. As shown, in some examples, the second creepage extension structure 440 may be on the second major side 104B of the housing 102 between the second semiconductor die 110 and the third semiconductor die 408 when viewed from a top plan view and/or a bottom plan view. For instance, as shown in FIG. 21, the second creepage extension structure 440 is between the second plurality of electrical leads 130 and the third plurality of electrical leads 420 along the housing plane H. That is, as shown, the third submount 412 may be spaced apart from the second submount 114 along the housing plane H, and the second creepage extension structure 440 may be between the second submount 114 and the third submount 412 along the housing plane H. Hence, the second creepage extension structure 440 may increase a creepage distance (e.g., shortest direct path along a surface between conductors at different voltage potentials) between the second plurality of electrical leads 130 and the third plurality of electrical leads 420. It should be understood that the second creepage extension structure 440 depicted in FIG. 20-22 is for purposes of illustration and discussion.

Those having ordinary skill in the art, using the disclosures provided herein, will understand that the power semiconductor device package 400 may include any of the creepage extension features described herein between the second portion 102B of the housing 102 and the third portion 102C of the housing 102 without deviating from the scope of the present disclosure. Furthermore, although depicted as having no creepage extension structures on the first major side 104A of the housing 102, those having ordinary skill in the art, using the disclosures provided herein, will understand that the power semiconductor device package 400 may include any number of creepage extension structures having any suitable shape and/or configuration on the first major side 104A of the housing without deviating from the scope of the present disclosure.

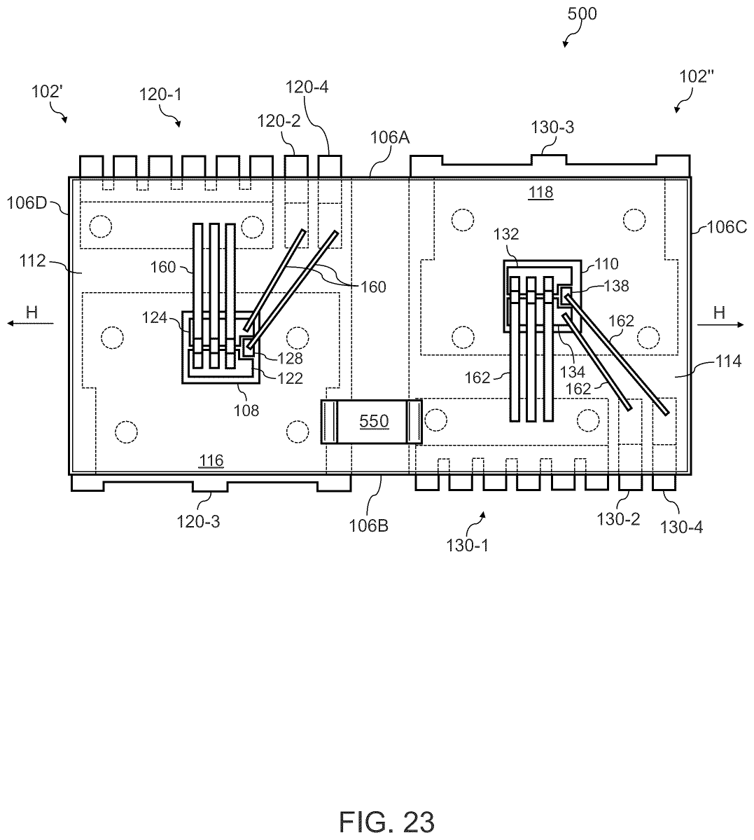

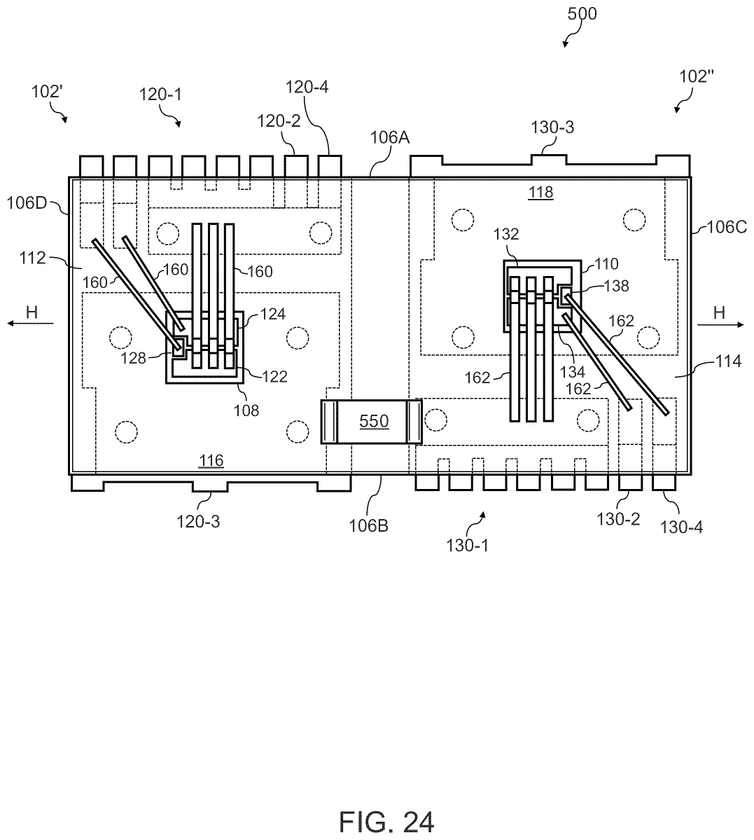

In some examples, power semiconductor device packages of the present disclosure may be configured in a half-bridge arrangement. By way of non-limiting example, FIG. 23-24 depict an example half-bridge power semiconductor device package 500 according to example embodiments of the present disclosure. The power semiconductor device package 500 may be similar to any of the power semiconductor device packages described herein, such as the power semiconductor device package 100 (FIG. 1-9), the power semiconductor device package 200 (FIG. 10-15), the power semiconductor device package 300 (FIG. 17-19), the power semiconductor device package 400 (FIG. 20-22), and/or the like. It should be understood that FIG. 23 is intended to represent structures for purposes of identification and description and are not intended to represent the structures to physical scale.

As shown in FIG. 23-24, the power semiconductor device package 500 may be similar to any of the power semiconductor device packages described herein, such as the power semiconductor device package 100 described above with reference to FIG. 1-9. However, in contrast to the power semiconductor device package 100 (FIG. 1-9), the power semiconductor device package 500 depicted in FIG. 23-24 is configured in a half-bridge arrangement. It should be understood that the power semiconductor device package 500 is depicted as being a variation of the power semiconductor device package 100 for purposes of illustration and discussion. Those having ordinary skill in the art, using the disclosures provided herein, will understand that any of the power semiconductor device packages described herein may be configured in a half-bridge arrangement without deviating from the scope of the present disclosure.

More particularly, referring now to FIG. 23, the power semiconductor device package 500 may include the first semiconductor die 108 on the first submount 112 and the second semiconductor die 110 on the second submount 114. As described herein, the first submount 112 may be and/or may include the first conductive structure 116, and the second submount 114 may be and/or may include the second conductive structure 118. The power semiconductor device package 500 may further include the first plurality of electrical leads 120 coupled to the first semiconductor die 108 and the second plurality of electrical leads 130 coupled to the second semiconductor die 110.

Referring still to FIG. 23, in contrast to the power semiconductor device package 100 (FIG. 1-9), the second semiconductor die 110 of the power semiconductor device package 500 may be rotated relative to the first semiconductor die 108, thereby allowing the power semiconductor device package 500 to be configured in a half-bridge arrangement. More particularly, as shown in FIG. 23, the source contact 132, the gate contact 134, and the additional contact 138 of the second semiconductor die 110 may be rotated such that the second semiconductor die 110 has a similar orientation (e.g., relative to the housing plane H) as the first semiconductor die 108. Due to the rotation of the second semiconductor die 110, the first lead 130-1, the second lead 130-2, and the fourth lead 130-4 of the second plurality of electrical leads 130 may likewise be rearranged such that the first lead 130-1 is proximate the third lead 120-3 of the first plurality of electrical leads 120. In this way, the first conductive structure 116 (and the third lead 120-3 of the first plurality of electrical leads 120) may be coupled to the first lead 130-1 of the second plurality of electrical leads 130 via an interface 550, thereby configuring the power semiconductor device package 500 in the half-bridge arrangement.

Referring now to FIG. 24, in some examples, the power semiconductor device package 500 may be configured in a symmetrical half-bridge arrangement. For instance, in contrast to the arrangement depicted in FIG. 23, the first semiconductor die 108 of the power semiconductor device package 500 may also be rotated relative to the second semiconductor die 110, thereby allowing the power semiconductor device package 500 to be configured in a symmetrical half-bridge arrangement. More particularly, as shown in FIG. 24, the source contact 122, the gate contact 124, and the additional contact 128 of the first semiconductor die 108 may be rotated such that the first semiconductor die 108 has an opposite orientation (e.g., relative to the housing plane H) as the second semiconductor die 110. That is, the first semiconductor die 108 and the second semiconductor die 110 may be arranged such that the additional contact 128 (of the first semiconductor die 108) and the additional contact 138 (of the second semiconductor die 110) are facing the first peripheral end 102′and the second peripheral end 102″, respectively. Due to the rotation of the first semiconductor die 108, the first lead 120-1, the second lead 120-2, and the fourth lead 120-4 of the first plurality of electrical leads 120 may likewise be rearranged such that the first lead 120-1 is proximate the third lead 130-3 of the second plurality of electrical leads 130. In this way, the first semiconductor die 108 (and the first plurality of electrical leads 120) and the second semiconductor die 110 (and the second plurality of electrical leads 130) may have a symmetrical arrangement with respect to the housing 102 of the half-bridge power semiconductor device package 500.

As described above, example power semiconductor device packages of the present disclosure include one or more submounts and/or one or more conductive structures that are, and/or form part of, a power substrate. By way of non-limiting example, FIG. 25A-25B depict a portion of an example power semiconductor device package 600 according to example embodiments of the present disclosure. The power semiconductor device package 600 may be similar to any of the power semiconductor device packages described herein, such as the power semiconductor device package 100 (FIG. 1-9), the power semiconductor device package 200 (FIG. 10-15), the power semiconductor device package 300 (FIG. 17-19), the power semiconductor device package 400 (FIG. 20-22), the power semiconductor device package 500 (FIG. 23), and/or the like. It should be understood that FIG. 25A-25B are intended to represent structures for purposes of identification and description and are not intended to represent the structures to physical scale.

More particularly, FIG. 25A-25B depict a top perspective view of a portion of the power semiconductor device package 600 with the housing 102 transparent. The power semiconductor device package 600 may be similar to any of the power semiconductor device packages described herein, such as the power semiconductor device package 100 described above with reference to FIG. 1-9. For purposes of illustration and discussion, the portion of the power semiconductor device package 600 depicted in FIG. 25A-25B may correspond to the second portion 102B of the power semiconductor device package 100 (FIG. 1-9). However, in contrast to the power semiconductor device package 100 (FIG. 1-9), the portion of the power semiconductor device package 600 depicted in FIG. 25A-25B includes a power substrate 650 which may, in some examples, be similar to the power substrate 350 discussed above with reference to FIG. 17-19. As shown, FIG. 25A-25B provide a cross-sectional view of the power substrate 650 taken along the housing plane H.

Referring now to FIG. 25A, the power substrate 650 may include a plurality of metal layers 652 and an insulating layer 654 between the metal layers 652. In some examples, the second conductive structure 118 may be or may include one of the plurality of metal layers 652, such as metal layer 652-1. Hence, in some examples, the second conductive structure 118 may be on the insulating layer 654. The insulating layer 654 may be formed from an insulating material, such as a ceramic material and/or other insulating materials. The insulating layer 654 may have another of the plurality of metal layers 652, such as metal layer 652-2, on a surface opposite metal layer 652-1 (e.g., conductive structure 118). In some examples, the metal layer 652-2 may be a thermal pad. More particularly, as described above, at least a portion of the power substrate 650, such as metal layer 652-2, may be at least partially exposed through the second major side 104B of the housing 102 to provide a thermally conductive heat dissipation path for the second semiconductor die 110 through the second major side 104B of the housing 102. As described herein, the second conductive structure 118 may be electrically coupled to the third lead 130-3 of the second plurality of electrical leads 130. As such, the insulating layer 654 may provide electrical isolation between the metal layer 652-2 (e.g., thermal pad) and the second plurality of electrical leads 130. Furthermore, in some examples, the power substrate 650 may be a direct bonded copper (DBC) substate. Additionally and/or alternatively, in some examples, the power substrate 650 may be an active metal brazed (AMB) substrate.

Referring now to FIG. 25B, in some examples, the second semiconductor die 110 may be on a lead frame, such as the second submount 114, and the lead frame may be on the power substrate 650. More particularly, as shown, the lead frame (e.g., second submount 114) may be on metal layer 652-1 of the power substrate 650. As shown, and as described above, at least a portion of the power substrate 650, such as metal layer 652-2, may be at least partially exposed through the second major side 104B of the housing 102 to provide a thermally conductive heat dissipation path for the second semiconductor die 110 through the second major side 104B of the housing 102.

Although only the second portion 102B of the power semiconductor device package 600 is depicted in FIG. 25A-25B, those having ordinary skill in the art, using the disclosures provided herein, will understand that one or more portions of any of the power semiconductor device packages described herein may include a power substrate. For instance, although not shown in the example depicted in FIG. 25A-25B, the first conductive structure 116 (not shown) may likewise be part of a power substrate that includes a plurality of metal layers and an insulating layer between the metal layers. In such examples, the first conductive structure 116 (not shown) may form part of a first power substrate, while the second conductive structure 118 may form part of a second power substrate (e.g., power substrate 650).

Furthermore, it should be noted that any of the power semiconductor device packages described herein may include power substrates on semiconductor die (e.g., FIG. 25A) and/or power substrates on lead frames (e.g., FIG. 25B). Those having ordinary skill in the art, using the disclosures provided herein, will understand that the example power substrate 650 may be used and/or integrated into any of the power semiconductor device packages described herein, such as any of the top-side cooled power semiconductor device packages, any of the bottom-side cooled power semiconductor device packages, any of the dual-side cooled power semiconductor device packages, and/or the like.

Variations and modifications may be made to the example power semiconductor device packages described herein (e.g., power semiconductor device package 100, 200, 300, 400) without deviating from the scope of the present disclosure. For instance, although depicted as a plurality of leadless SMT connection structures, the first plurality of electrical leads 120, the second plurality of electrical leads 130, and/or the third plurality of electrical leads 420 may have any suitable electrical connection pin. By way of non-limiting illustrative example, FIG. 26A-26B depict various other electrical pins for any of the electrical leads described herein. More particularly, FIG. 26A depicts example extended leads for any of the plurality of electrical leads described herein, and FIG. 26B depicts example Gull-wing pins for any of the plurality of electrical leads described herein. It should be understood that the extended leads depicted in FIG. 26A and the Gull-wing pins depicted in FIG. 26B are for purposes of illustration and discussion. Those having ordinary skill in the art, using the disclosures provided herein, will understand that any suitable electrical pin and/or any suitable combination of electrical pins may be used without deviating from the scope of the present disclosure.

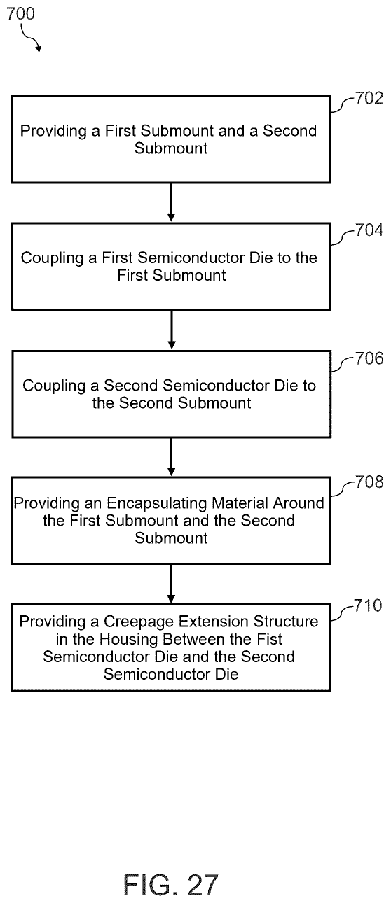

FIG. 27 depicts a flow chart diagram of an example method 700 according to example embodiments of the present disclosure. FIG. 27 depicts example process steps for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 702, the method 700 includes providing a first submount and a second submount.

At 704, the method 700 includes coupling a first semiconductor die to the first submount. The first submount may be a first lead frame, a first power substrate, and/or the like. In some examples, the first semiconductor die may be directly attached to the first submount with a die-attach material, such as a metal sintering die-attach (e.g., silver (Ag) or copper (Cu)), conductive adhesive die-attach, and/or the like. The first semiconductor die may include a wide bandgap semiconductor material, such as silicon carbide (SiC), a Group-III nitride, and/or the like. In some examples, the first semiconductor die includes a metal-oxide-semiconductor field-effect transistor (MOSFET). Additionally and/or alternatively, in some examples, the first semiconductor die includes a Schottky diode.

At 706, the method 700 includes coupling a second semiconductor die to the second submount. The second submount may be a second lead frame, a second power substrate, and/or the like. In some examples, the second semiconductor die may be directly attached to the second submount with a die-attach material, such as a metal sintering die-attach (e.g., silver (Ag) or copper (Cu)), conductive adhesive die-attach, and/or the like. The second semiconductor die may include a wide bandgap semiconductor material, such as silicon carbide (SiC), a Group-III nitride, and/or the like. In some examples, the second semiconductor die includes a metal-oxide-semiconductor field-effect transistor (MOSFET). Additionally and/or alternatively, in some examples, the second semiconductor die includes a Schottky diode.

At 708, the method 700 includes providing an encapsulating material around the first submount and the second submount, the encapsulating material forming a housing. In some examples, the encapsulating material may be provided around the first submount and the second submount such that each of the first submount and the second submount are within the housing. In some examples, the encapsulating material may be provided around the first submount and the second submount such that at least a portion of the first submount and the second submount are at least partially exposed through a major side of the housing.

At 710, the method 700 includes providing a creepage extension structure in the housing between the first semiconductor die and the second semiconductor die. More particularly, in some examples, the creepage extension structure may be provided between the first submount and the second submount. The creepage extension structure may have a depth in a range of about 0.25 microns to about 2 microns, such as a range of about 0.5 microns to about 1 micron, such as about 0.8 microns. The creepage extension structure may include at least two sidewall segments, such as at least six sidewall segments, such as at least eight sidewall segments. In some examples, the creepage extension structure may be a rectangular creepage extension structure. In other examples, the creepage extension structure may be a non-rectangular creepage extension structure. By way of non-limiting, the creepage extension structure may be a step structure, a trench defined between the first semiconductor die and the second semiconductor die, and/or the like.

In some examples, the creepage extension structure may be provided on the first major side of the housing. In some examples, the creepage extension structure may be provided on the second major side of the housing. In some examples, one or more creepage extension structures may be provided on the first major side and the second major side of the housing. By way of non-limiting example, a first creepage extension structure may be provided on a first major side of the housing between the first semiconductor die and the second semiconductor die, and a second creepage extension structure may be provided on a second major side of the housing that is opposite the first major side. In some examples, the second creepage extension structure may be provided between, and may provide a creepage distance between, a source contact of the first semiconductor die and a drain contact of the second semiconductor die. Additionally and/or alternatively, a third creepage extension structure may be provided on the second major side of the housing. The third creepage extension structure may be spaced apart from the second creepage extension structure on the second major side of the housing. In some examples, the third creepage extension structure may be provided between, and may provide a creepage distance between, a source contact of the first semiconductor die and a drain contact of the second semiconductor die. In some examples, the third creepage extension structure may have a same shape as the second creepage extension structure. Additionally and/or alternatively, in some examples, the third creepage extension structure may have a different shape than the second creepage extension structure.

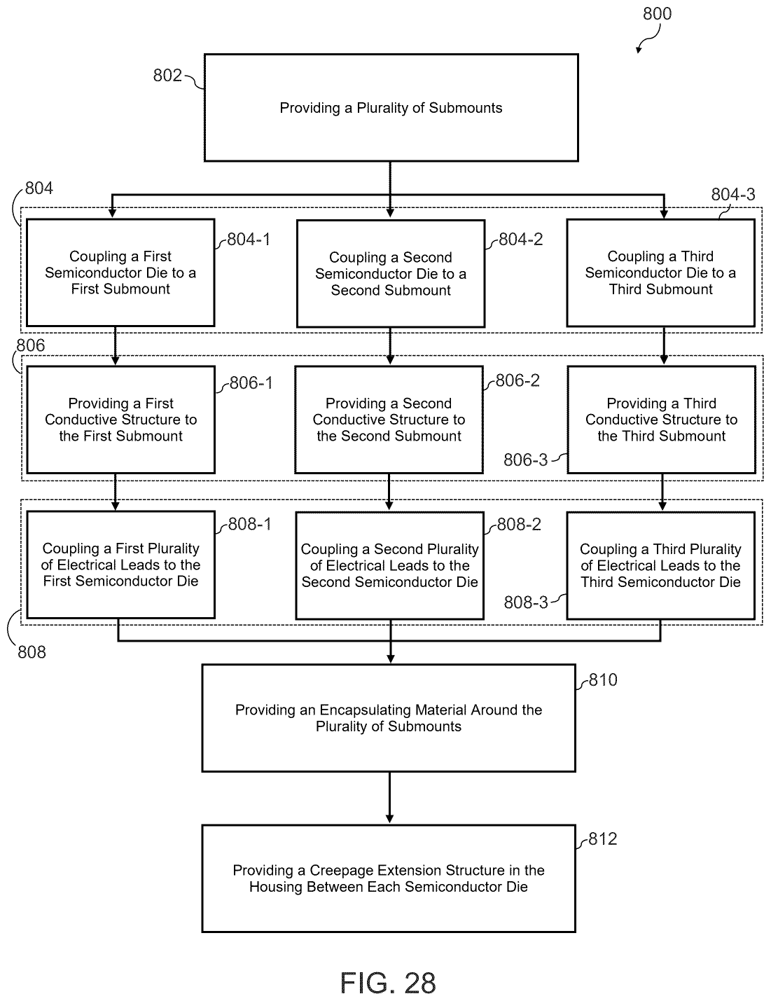

FIG. 28 depicts a flow chart diagram of an example method 800 according to example embodiments of the present disclosure. FIG. 28 depicts example process steps for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 802, the method 800 includes providing a plurality of submounts. The plurality of submounts may be similar to any of the submounts described herein. For instance, the submounts may be lead frames, power substrates, and/or the like. By way of non-limiting example, a first submount, a second submount, and a third submount may be provided. It should be understood that any number of submounts may be provided without deviating from the scope of the present disclosure.

At 804, the method 800 includes coupling a semiconductor die to each of the plurality of submounts. The semiconductor die may be similar to any of the semiconductor die described herein. More particularly, at 804-1, the method 800 includes coupling a first semiconductor die to the first submount. At 804-2, the method 800 includes coupling a second semiconductor die to the second submount. At 804-3, the method 800 includes coupling a third semiconductor die to the third submount. It should be understood that any number of semiconductor die may be provided without deviating from the scope of the present disclosure.

At 806, the method 800 includes coupling a conductive structure to each submount. The conductive structures may be similar to any of the conductive structures described herein. More particularly, at 806-1, the method 800 includes coupling a first conductive structure to the first submount. For instance, in some examples, the method 800 may include providing a first power substrate and coupling the first submount (e.g., first lead frame) to the first power substrate. At 806-2, the method 800 includes coupling a second conductive structure to the second submount. For instance, in some examples, the method 800 may include providing a second power substrate and coupling the second submount (e.g., second lead frame) to the second power substrate. At 806-3, the method 800 includes coupling a third conductive structure to the third submount. For instance, in some examples, the method 800 may include providing a third power substrate and coupling the third submount (e.g., third lead frame) to the third power substrate. It should be understood that any number of conductive structures may be provided without deviating from the scope of the present disclosure.

At 808, the method 800 includes coupling a plurality of electrical leads to each of the semiconductor die. The plurality of electrical leads may be similar to any of the electrical leads described herein. More particularly, at 808-1, the method 800 includes coupling a first plurality of electrical leads to the first semiconductor die. At 808-2, the method 800 includes coupling a second plurality of electrical leads to the second semiconductor die. At 808-3, the method 800 includes coupling a third plurality of electrical leads to the third semiconductor die. It should be understood that any number of electrical leads may be provided without deviating from the scope of the present disclosure.

At 810, the method 800 includes providing an encapsulating material around the plurality of submounts. The encapsulating material may be similar to any encapsulating material described herein. More particularly, the encapsulating material may be provided around the first submount, the second submount, and the third submount to form a housing. In some examples, the encapsulating material may be provided around the first submount, the second submount, and the third submount such that each of the first submount, the second submount, and the third submount are within the housing. In some examples, the encapsulating material may be provided around the first submount, the second submount, and the third submount such that at least a portion of the first submount, the second submount, and the third submount are at least partially exposed through a major side of the housing. It should be understood that the encapsulating material may be provided around any number of submounts without deviating from the scope of the present disclosure.

At 812, the method 800 includes providing a creepage extension structure in the housing between each semiconductor die. The creepage extension structure may be similar to any of the creepage extension structures described herein. More particularly, a first creepage extension structure may be provided between the first semiconductor die and the second semiconductor die, and a second creepage extension structure may be provided between the second semiconductor die and the third semiconductor die. For instance, in some examples, the first creepage extension structure may be provided between the first submount and the second submount, and the second creepage extension structure may be provided between the second submount and the third submount. In some examples, one or more additional creepage extension structures may be provided on an opposing side of the housing relative to the first creepage extension structure and the second creepage extension structure. It should be understood that any number of creepage extension structures may be provided in the housing without deviating from the scope of the present disclosure.

Example aspects of the present disclosure are set forth below. Any of the below features or examples may be used in combination with any of the embodiments or features provided in the present disclosure.

One example aspect of the present disclosure is directed to a power semiconductor device package. The power semiconductor device package includes a housing, a first semiconductor die on a first submount, a second semiconductor die on a second submount, and a creepage extension structure in the housing. At least a portion of the creepage extension structure is between the first semiconductor die and the second semiconductor die.

In some examples, the first submount is a first power substrate, the first power substrate comprising a plurality of metal layers and an insulating layer between the metal layers, and the second submount is a second power substrate, the second power substrate comprising a plurality of metal layers and an insulating layer between the metal layers.

In some examples, at least a portion of the first power substrate is at least partially exposed through a major side of the housing at least a portion the second power substrate is at least partially exposed through the major side of the housing.

In some examples, the first power substrate and the second power substrate are one of direct bonded copper (DBC) substrates or active metal brazed (AMB) substrates.

In some examples, the first submount is a first lead frame and the second submount is a second lead frame.

In some examples, at least a portion of the first lead frame is at least partially exposed through a major side of the housing, and at least a portion of the second lead frame is at least partially exposed through the major side of the housing.

In some examples, the first lead frame is on a first power substrate, the first power substrate comprising a plurality of metal layers and an insulating layer between the metal layers, and the second lead frame is on a second power substrate, the second power substrate comprising a plurality of metal layers and an insulating layer between the metal layers.

In some examples, at least a portion of the first power substrate is at least partially exposed through a major side of the housing, and at least a portion of the second power substrate is at least partially exposed through the major side of the housing.

In some examples, the first semiconductor die is directly coupled to the first submount, and the second semiconductor die is directly coupled to the second submount.

In some examples, the first semiconductor die is electrically isolated from the second semiconductor die.

In some examples, the first semiconductor die and the second semiconductor die are within the housing.

In some examples, the first semiconductor die and the second semiconductor die include a common drain.

In some examples, the creepage extension structure has a depth in a range of about 0.5 microns to about 1 micron.

In some examples, the power semiconductor device package further includes a first plurality of electrical leads coupled to the first semiconductor die and extending from the housing and a second plurality of electrical leads coupled to the second semiconductor die and extending from the housing.

In some examples, each of the first plurality of electrical leads and the second plurality of electrical leads are a plurality of surface mount type (SMT) connection structures.

In some examples, the creepage extension structure provides a creepage distance between the first plurality of electrical leads and the second plurality of electrical leads.

In some examples, the first plurality of electrical leads comprises a first lead, a second lead, and a third lead, and the second plurality of electrical leads comprises a first lead, a second lead, and a third lead.

In some examples, the first lead and the second lead of the first plurality of electrical leads extend from an opposing side of the housing relative to the first lead and the second lead of the second plurality of electrical leads.

In some examples, for the first plurality of electrical leads, the first lead and the second lead extend from a first minor side of the housing and the third lead extends from a second minor side of the housing that is opposite the first minor side. In some examples, for the second plurality of electrical leads, the first lead and the second lead extend from the second minor side of the housing and the third lead extends from the first minor side of the housing.

In some examples, for the first plurality of electrical leads, the first lead is coupled to a source contact of the first semiconductor die, the second lead is coupled to a gate contact of the first semiconductor die, and the third lead is coupled to a drain contact of the first semiconductor die. In some examples, for the second plurality of electrical leads, the first lead is coupled to a source contact of the second semiconductor die, the second lead is coupled to a gate contact of the second semiconductor die, and the third lead is coupled to a drain contact of the second semiconductor die.

In some examples, the creepage extension structure comprises a first creepage portion, a second creepage portion, and a third creepage portion. In some examples, the first creepage portion is between the first semiconductor die and the second semiconductor die, the second creepage portion is perpendicular to the first creepage portion and extends laterally between the first creepage portion and a first peripheral end of the housing, and the third creepage portion is perpendicular to the first creepage portion and extends laterally between the first creepage portion and a second peripheral end of the housing opposite the first peripheral end.

In some examples, the first creepage portion of the creepage extension structure extends from the first minor side to the second minor side of the housing.

In some examples, the second creepage portion of the creepage extension structure provides a creepage distance between the first lead and the third lead of the first plurality of electrical leads, and the third creepage portion of the creepage extension structure provides a creepage distance between the first lead and the third lead of the second plurality of electrical leads.

In some examples, each of the first plurality of electrical leads and the second plurality of electrical leads comprise a plurality of Gull-wing pins.

In some examples, the housing comprises a first major side and a second major side opposite the first major side.

In some examples, the first submount comprises a first conductive structure, and the second submount comprises a second conductive structure.

In some examples, the power semiconductor device package further includes a third conductive structure on an opposing side of the first semiconductor die relative to the first conductive structure and a fourth conductive structure on an opposing side of the second semiconductor die relative to the second conductive structure.

In some examples, the first conductive structure and the second conductive structure are at least partially exposed through the first major side of the housing, and the third conductive structure and the fourth conductive structure are at least partially exposed through the second major side of the housing.

In some examples, the first conductive structure is a first power substrate, the first power substrate comprising a plurality of metal layers and an insulating layer between the metal layers. In some examples, the second conductive structure is a second power substrate, the second power substrate comprising a plurality of metal layers and an insulating layer between the metal layers. In some examples, the third conductive structure is a first lead frame, and the fourth conductive structure is a second lead frame.

In some examples, the first conductive structure and the second conductive structure are at least partially exposed through the first major side of the housing.

In some examples, the first conductive structure and the second conductive structure are at least partially exposed through the second major side of the housing.

In some examples, the first conductive structure and the second conductive structure are thermally conductive.

In some examples, the first conductive structure and the second conductive structure are electrically conductive.

In some examples, the creepage extension structure comprises a step structure.

In some examples, the creepage extension structure comprises a trench defined between the first semiconductor die and the second semiconductor die.

In some examples, the creepage extension structure comprises at least two sidewall segments.

In some examples, the creepage extension structure comprises at least six sidewall segments.

In some examples, the creepage extension structure comprises at least eight sidewall segments.

In some examples, the creepage extension structure is a rectangular creepage extension structure.

In some examples, the creepage extension structure is a non-rectangular creepage extension structure.

In some examples, the creepage extension structure is a first creepage extension structure, and the power semiconductor device package further comprises a second creepage extension structure in the housing, the second creepage extension structure on a major side of the housing opposite the first creepage extension structure.

In some examples, the power semiconductor device package further includes a third creepage extension structure in the housing, the third creepage extension structure on a same major side of the housing as the second creepage extension structure.

In some examples, the second creepage extension structure has a same shape as the third creepage extension structure.

In some examples, the second creepage extension structure has a different shape than the third creepage extension structure.

In some examples, the second creepage extension structure is between a drain contact of the first semiconductor die and a source contact of the second semiconductor die, and the third creepage extension structure is between a source contact of the first semiconductor die and a drain contact of the second semiconductor die.

In some examples, the power semiconductor device package further includes a third semiconductor die on a third submount.

In some examples, the creepage extension structure is a first creepage extension structure, and the power semiconductor device package further includes a second creepage extension structure in the housing between the second semiconductor die and the third semiconductor die.

In some examples, the first semiconductor die is coupled to the first submount with a die-attach material, and the second semiconductor die is coupled to the second submount with a die-attach material.

In some examples, the first semiconductor die and the second semiconductor die include a wide bandgap semiconductor material, the wide bandgap semiconductor material being one of silicon carbide (SiC) or a Group-III nitride.

In some examples, each of the first semiconductor die and the second semiconductor die include a metal-oxide-semiconductor field-effect transistor (MOSFET).

In some examples, each of the first semiconductor die and the second semiconductor die include a Schottky diode.

Another example aspect of the present disclosure is directed to a power semiconductor device package. The power semiconductor device package includes a housing, a first semiconductor die on a first submount, and a second semiconductor die on a second submount that is electrically isolated from the first submount.

In some examples, the first submount includes a first conductive structure, and the second submount includes a second conductive structure.

In some examples, the power semiconductor device package further includes a third conductive structure on an opposing side of the first semiconductor die relative to the first conductive structure and a fourth conductive structure on an opposing side of the second semiconductor die relative to the second conductive structure.

In some examples, the housing comprises a first major side and a second major side. In some examples, the first conductive structure and the second conductive structure are at least partially exposed through the first major side of the housing, and the third conductive structure and the fourth conductive structure are at least partially exposed through the second major side of the housing.

In some examples, the first conductive structure is a first power substrate, the first power substrate comprising a plurality of metal layers and an insulating layer between the metal layers. In some examples, the second conductive structure is a second power substrate, the second power substrate comprising a plurality of metal layers and an insulating layer between the metal layers. In some examples, the third conductive structure is a first lead frame, and the fourth conductive structure is a second lead frame.

In some examples, the housing comprises a first major side and a second major side opposite the first major side, and the first conductive structure and the second conductive structure are at least partially exposed through the first major side of the housing.

In some examples, the housing comprises a first major side and a second major side opposite the first major side, and the first conductive structure and the second conductive structure are at least partially exposed through the second major side of the housing.

In some examples, the first conductive structure and the second conductive structure are thermally conductive.

In some examples, the first conductive structure and the second conductive structure are electrically conductive.

In some examples, the first submount is a first lead frame, and the second submount is a second lead frame.

In some examples, at least a portion of the first lead frame is at least partially exposed through a major side of the housing, and at least a portion of the second lead frame is at least partially exposed through the major side of the housing.

In some examples, the first lead frame is on a first power substrate, the first power substrate comprising a plurality of metal layers and an insulating layer between the metal layers, and the second lead frame is on a second power substrate, the second power substrate comprising a plurality of metal layers and an insulating layer between the metal layers.

In some examples, at least a portion of the first power substrate is at least partially exposed through a major side of the housing, and at least a portion of the second power substrate is at least partially exposed through the major side of the housing.

In some examples, the power semiconductor device package further includes a third semiconductor die on a third submount.

In some examples, the first semiconductor die and the second semiconductor die include a common drain.

In some examples, the power semiconductor device package further includes a first plurality of electrical leads coupled to the first semiconductor die and extending from the housing and a second plurality of electrical leads coupled to the second semiconductor die and extending from the housing. In some examples, the first plurality of electrical leads includes a first lead coupled to a source contact of the first semiconductor die, a second lead coupled to a gate contact of the first semiconductor die, and a third lead coupled to a drain contact of the first semiconductor die. In some examples, the second plurality of electrical leads includes a first lead coupled to a source contact of the second semiconductor die, a second lead coupled to a gate contact of the second semiconductor die, and a third lead coupled to a drain contact of the second semiconductor die.

In some examples, the first lead and the second lead of the first plurality of electrical leads extend from an opposing side of the housing relative to the first lead and the second lead of the second plurality of electrical leads.

In some examples, for the first plurality of electrical leads, the first lead and the second lead extend from a first minor side of the housing, and the third lead extends from a second minor side of the housing that is opposite the first minor side. In some examples, for the second plurality of electrical leads, the first lead and the second lead extend from the second minor side of the housing, and the third lead extends from the first minor side of the housing.

In some examples, each of the first plurality of electrical leads and the second plurality of electrical leads are one of a plurality of surface mount type (SMT) connection structures or a plurality of Gull-wing pins.

In some examples, the power semiconductor device package further includes a creepage extension structure in the housing between the first semiconductor die and the second semiconductor die, the creepage extension structure having a depth in a range of about 0.5 microns to about 1 micron.

In some examples, the creepage extension structure includes a first creepage portion, a second creepage portion, and a third creepage portion. In some examples, the first creepage portion is between the first semiconductor die and the second semiconductor die, the second creepage portion is perpendicular to the first creepage portion and extends laterally between the first creepage portion and a first peripheral end of the housing, and the third creepage portion is perpendicular to the first creepage portion and extends laterally between the first creepage portion and a second peripheral end of the housing opposite the first peripheral end.

In some examples, the first creepage portion of the creepage extension structure extends from a first minor side of the housing to a second minor side of the housing that is opposite the first minor side.

In some examples, the creepage extension structure includes one of a step structure or a trench defined between the first semiconductor die and the second semiconductor die.

In some examples, the creepage extension structure is a rectangular creepage extension structure.

In some examples, the creepage extension structure is a non-rectangular creepage extension structure.

In some examples, the creepage extension structure is a first creepage extension structure, and the power semiconductor device package further includes a second creepage extension structure in the housing, the second creepage extension structure on a major side of the housing opposite the first creepage extension structure.

In some examples, the power semiconductor device package further includes a third creepage extension structure in the housing, the third creepage extension structure on a same major side of the housing as the second creepage extension structure.

In some examples, the second creepage extension structure has a same shape as the third creepage extension structure.

In some examples, the second creepage extension structure has a different shape than the third creepage extension structure.

In some examples, the second creepage extension structure is between a drain contact of the first semiconductor die and a source contact of the second semiconductor die, and the third creepage extension structure is between a source contact of the first semiconductor die and a drain contact of the second semiconductor die.

In some examples, the first submount is part of a first power substrate, the first power substrate comprising a plurality of metal layers and an insulating layer between the metal layers, and the second submount is part of a second power substrate, the second power substrate comprising a plurality of metal layers and an insulating layer between the metal layers.

In some examples, at least a portion of the first power substrate is at least partially exposed through a major side of the housing, and at least a portion the second power substrate is at least partially exposed through the major side of the housing.

In some examples, the first power substrate and the second power substrate are one of direct bonded copper (DBC) substrates or active metal brazed (AMB) substrates.

In some examples, the first semiconductor die and the second semiconductor die includes a wide bandgap semiconductor material, the wide bandgap semiconductor material being one of silicon carbide (SiC) or a Group-III nitride.

In some examples, each of the first semiconductor die and the second semiconductor die include a metal-oxide-semiconductor field-effect transistor (MOSFET).

In some examples, each of the first semiconductor die and the second semiconductor die include a Schottky diode.

Another example aspect of the present disclosure is directed to a method. The method includes providing a first submount and a second submount. The method further includes coupling a first semiconductor die to the first submount. The method further includes coupling a second semiconductor die to the second submount. The method further includes providing an encapsulating material around the first submount and the second submount, the encapsulating material forming a housing. The method further includes providing a creepage extension structure in the housing between the first semiconductor die and the second semiconductor die.

In some examples, the first submount is a first lead frame, and the second submount is a second lead frame.

In some examples, providing the encapsulating material includes providing the encapsulating material around the first lead frame such that at least a portion of the first lead frame is at least partially exposed through a major side of the housing, and providing the encapsulating material around the second lead frame such that at least a portion of the second lead frame is at least partially exposed through the major side of the housing.

In some examples, the method further includes providing a first power substrate and a second power substrate, each of the first power substrate and the second power substrate respectively comprising a plurality of metal layers and an insulating layer between the metal layers. In some examples, the method further includes coupling the first power substrate to the first lead frame and coupling the second power substrate to the second lead frame.

In some examples, providing the encapsulating material includes providing the encapsulating material around the first lead frame and the first power substrate such that at least a portion of the first power substrate is at least partially exposed through a major side of the housing, and providing the encapsulating material around the second lead frame and the second power substrate such that at least a portion of the second power substrate is at least partially exposed through the major side of the housing.

In some examples, the method further includes providing a third submount and coupling a third semiconductor die to the third submount.

In some examples, providing the encapsulating material includes providing the encapsulating material around the first submount, the second submount, and the third submount to form the housing.

In some examples, the creepage extension structure is a first creepage extension structure, and the method further includes providing a second creepage extension structure in the housing between the second semiconductor die and the third semiconductor die.

In some examples, coupling the first semiconductor die to the first submount includes directly attaching the first semiconductor die to the first submount with a die-attach material.

In some examples, coupling the second semiconductor die to the second submount includes directly attaching the second semiconductor die to the second submount with a die-attach material.

In some examples, the first submount is a first power substrate and the second submount is a second power substrate, each of the first power substrate and the second power substrate respectively comprising a plurality of metal layers and an insulating layer between the metal layers.

In some examples, providing the encapsulating material includes providing the encapsulating material around the first power substrate such that at least a portion of the first power substrate is at least partially exposed through a major side of the housing and providing the encapsulating material around the second power substrate such that at least a portion of the second power substrate is at least partially exposed through the major side of the housing.

In some examples, the method further includes providing a first conductive structure to the first submount and providing a second conductive structure to the second submount.

In some examples, providing the encapsulating material includes providing the encapsulating material around the first submount, the first semiconductor die, the first conductive structure, the second submount, the second semiconductor die, and the second conductive structure to form the housing.

In some examples, the method further includes providing a third conductive structure on an opposing side of the first semiconductor die relative to the first conductive structure and providing a fourth conductive structure on an opposing side of the second semiconductor die relative to the second conductive structure.

In some examples, providing the encapsulating material includes providing the encapsulating material around the first conductive structure, the first submount, the first semiconductor die, and the third conductive structure such that at least a portion of the first conductive structure is at least partially exposed through a first major side of the housing and at least a portion of the third conductive structure is at least partially exposed through a second major side of the housing that is opposite the first major side. In some examples, the method further includes providing the encapsulating material around the second conductive structure, the second submount, the second semiconductor die, and the fourth conductive structure such that at least a portion of the second conductive structure is at least partially exposed through the first major side of the housing and at least a portion of the fourth conductive structure is at least partially exposed through the second major side of the housing.

In some examples, the first conductive structure is a first power substrate, the first power substrate comprising a plurality of metal layers and an insulating layer between the metal layers. In some examples, the second conductive structure is a second power substrate, the second power substrate comprising a plurality of metal layers and an insulating layer between the metal layers. In some examples, the third conductive structure is a first lead frame, and the fourth conductive structure is a second lead frame.

In some examples, the method further includes coupling a first plurality of electrical leads to the first semiconductor die, each of the first plurality of electrical leads extending from the housing and coupling a second plurality of electrical leads to the second semiconductor die, each of the second plurality of electrical leads extending from the housing.

In some examples, coupling the first plurality of electrical leads to the first semiconductor die includes coupling a first lead to a source contact of the first semiconductor die, coupling a second lead to a gate contact of the first semiconductor die, and coupling a third lead to a drain contact of the first semiconductor die.

In some examples, coupling the second plurality of electrical leads to the second semiconductor die includes coupling a first lead to a source contact of the second semiconductor die, coupling a second lead to a gate contact of the second semiconductor die, and coupling a third lead to a drain contact of the second semiconductor die.

In some examples, providing the creepage extension structure in the housing includes providing a first creepage portion of the creepage extension structure between the first semiconductor die and the second semiconductor die, the first creepage portion extending from a first minor side of the housing to a second minor side of the housing that is opposite the first minor side; providing a second creepage portion of the creepage extension structure between the first lead and the third lead of the first plurality of electrical leads, the second creepage portion being perpendicular to the first creepage portion, the second creepage portion extending laterally between the first creepage portion and a first peripheral end of the housing; and providing a third creepage portion of the creepage extension structure between the first lead and the third lead of the second plurality of electrical leads, the third creepage portion being perpendicular to the first creepage portion, the third creepage portion extending laterally between the first creepage portion and a second peripheral end of the housing that is opposite the first peripheral end.

In some examples, providing the creepage extension structure in the housing includes providing the creepage extension structure in the housing between the first plurality of electrical leads and the second plurality of electrical leads.

In some examples, providing the creepage extension structure in the housing includes providing a first creepage extension structure on a first major side of the housing between the first semiconductor die and the second semiconductor die and providing a second creepage extension structure on a second major side of the housing between the first semiconductor die and the second semiconductor die, the second major side being opposite the first major side.

In some examples, providing the creepage extension structure in the housing further includes providing a third creepage extension structure on the second major side of the housing between the first semiconductor die and the second semiconductor die. In some examples, the third creepage extension structure is spaced apart from the second creepage extension structure on the second major side of the housing.

In some examples, the second creepage extension structure has a same shape as the third creepage extension structure.

In some examples, the second creepage extension structure has a different shape than the third creepage extension structure.

In some examples, the second creepage extension structure is between a drain contact of the first semiconductor die and a source contact of the second semiconductor die, and the third creepage extension structure is between a source contact of the first semiconductor die and a drain contact of the second semiconductor die.

In some examples, the first semiconductor die and the second semiconductor die include a wide bandgap semiconductor material, the wide bandgap semiconductor material being one of silicon carbide (SiC) or a Group-III nitride.

In some examples, each of the first semiconductor die and the second semiconductor die include one of a metal-oxide-semiconductor field-effect transistor (MOSFET) or a Schottky diode.

Another example aspect of the present disclosure is directed to a power semiconductor device package. The power semiconductor device package includes a housing, a first semiconductor die on a first submount, a second semiconductor die on a second submount, and a creepage extension structure in the housing between the first semiconductor die and the second semiconductor die. The creepage extension structure includes a first creepage portion between the first semiconductor die and the second semiconductor die, a second creepage portion perpendicular to the first creepage portion and extending laterally from the first creepage portion towards the first semiconductor die, and a third creepage portion perpendicular to the first creepage portion and extending laterally from the first creepage portion towards the second semiconductor die.

In some examples, the creepage extension structure has a depth in a range of about 0.5 microns to about 1 micron.

In some examples, the creepage extension structure comprises a step structure.

In some examples, the creepage extension structure includes a trench defined between the first semiconductor die and the second semiconductor die.

In some examples, the creepage extension structure is a first creepage extension structure, and the power semiconductor device package further includes a second creepage extension structure in the housing, the second creepage extension structure on a major side of the housing opposite the first creepage extension structure.

In some examples, the power semiconductor device package further includes a third creepage extension structure in the housing. In some examples, the third creepage extension structure is on a same major side of the housing as the second creepage extension structure.

In some examples, the second creepage extension structure has a same shape as the third creepage extension structure.

In some examples, the second creepage extension structure has a different shape than the third creepage extension structure.

In some examples, the second creepage extension structure is between a drain contact of the first semiconductor die and a source contact of the second semiconductor die, and the third creepage extension structure is between a source contact of the first semiconductor die and a drain contact of the second semiconductor die.

In some examples, the power semiconductor device package further includes a first plurality of electrical leads coupled to the first semiconductor die and extending from the housing and a second plurality of electrical leads coupled to the second semiconductor die and extending from the housing. In some examples, the first plurality of electrical leads include a first lead coupled to a source contact of the first semiconductor die, a second lead coupled to a gate contact of the first semiconductor die, and a third lead coupled to a drain contact of the first semiconductor die. In some examples, the second plurality of electrical leads include a first lead coupled to a source contact of the second semiconductor die, a second lead coupled to a gate contact of the second semiconductor die, and a third lead coupled to a drain contact of the second semiconductor die.

In some examples, for the first plurality of electrical leads the first lead and the second lead extend from a first minor side of the housing, and the third lead extends from a second minor side of the housing that is opposite the first minor side. In some examples, for the second plurality of electrical leads, the first lead and the second lead extend from the second minor side of the housing, and the third lead extends from the first minor side of the housing.

In some examples, the creepage extension structure provides a creepage distance between the first plurality of electrical leads and the second plurality of electrical leads.

In some examples, the second creepage portion of the creepage extension structure provides a creepage distance between the first lead and the third lead of the first plurality of electrical leads, and the third creepage portion of the creepage extension structure provides a creepage distance between the first lead and the third lead of the first plurality of electrical leads.

In some examples, each of the first semiconductor die and the second semiconductor die include one of a metal-oxide-semiconductor field-effect transistor (MOSFET) or a Schottky diode.

Another example aspect of the present disclosure is directed to a power semiconductor device package. The power semiconductor device package includes a housing having a major surface. The housing defines a housing plane. The power semiconductor device package further includes a first semiconductor die on a first submount. The first semiconductor die defines a first portion of the housing. The power semiconductor device package further includes a first plurality of electrical leads extending from the first portion of the housing. The power semiconductor device package further includes a second semiconductor die on a second submount. The second semiconductor die defines a second portion of the housing that is different from the first portion. The power semiconductor device package further includes a second plurality of electrical leads extending from the second portion of the housing. The second plurality of electrical leads are rotated 180-degrees about the housing plane relative to the first plurality of electrical leads.

In some examples, the first submount is a first power substrate, the first power substrate comprising a plurality of metal layers and an insulating layer between the metal layers. In some examples, the second submount is a second power substrate, the second power substrate comprising a plurality of metal layers and an insulating layer between the metal layers.

In some examples, the first submount is a first lead frame and the second submount is a second lead frame.

In some examples, at least a portion of the first submount is at least partially exposed through the major surface of the housing, and at least a portion of the second submount is at least partially exposed through the major surface of the housing.

Another example aspect of the present disclosure is directed to a power semiconductor device package. The power semiconductor device package includes a housing, a first semiconductor die on a first submount, a first plurality of electrical leads coupled to the first semiconductor die and extending from the housing, a second semiconductor die on a second submount, and a second plurality of electrical leads coupled to the second semiconductor die and extending from the housing. The first plurality of electrical leads includes a first lead coupled to a source contact of the first semiconductor die, a second lead coupled to a gate contact of the first semiconductor die, and a third lead coupled to a drain contact of the first semiconductor die. The second plurality of electrical leads includes a first lead coupled to a source contact of the second semiconductor die, a second lead coupled to a gate contact of the second semiconductor die, and a third lead coupled to a drain contact of the second semiconductor die. The first lead and the second lead of the first plurality of electrical leads extend from an opposing side of the housing relative to the first lead and the second lead of the second plurality of electrical leads.

In some examples, the first submount is a first power substrate, the first power substrate comprising a plurality of metal layers and an insulating layer between the metal layers. In some examples, the second submount is a second power substrate, the second power substrate comprising a plurality of metal layers and an insulating layer between the metal layers.

In some examples, the first submount is a first lead frame and the second submount is a second lead frame.

In some examples, at least a portion of the first submount is at least partially exposed through a major side of the housing, and at least a portion of the second submount is at least partially exposed through the major side of the housing.

Another example aspect of the present disclosure is directed to a power semiconductor device package. The power semiconductor device package includes a housing, a first semiconductor die on a first submount, and a second semiconductor die on a second submount. The first semiconductor die and the second semiconductor die are arranged within the housing in a half-bridge arrangement.

In some examples, the first submount is a first power substrate, the first power substrate comprising a plurality of metal layers and an insulating layer between the metal layers. In some examples, the second submount is a second power substrate, the second power substrate comprising a plurality of metal layers and an insulating layer between the metal layers.

In some examples, the first submount is a first lead frame and the second submount is a second lead frame.

In some examples, at least a portion of the first submount is at least partially exposed through a major side of the housing, and at least a portion of the second submount is at least partially exposed through the major side of the housing.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A power semiconductor device package, comprising:
a housing;
a first semiconductor die on a first submount;
a second semiconductor die on a second submount; and
a creepage extension structure in the housing, at least a portion of the creepage extension structure between the first semiconductor die and the second semiconductor die.

2. The power semiconductor device package of claim 1, wherein:
the first submount is a first power substrate, the first power substrate comprising a plurality of metal layers and an insulating layer between the metal layers; and
the second submount is a second power substrate, the second power substrate comprising a plurality of metal layers and an insulating layer between the metal layers.

3. The power semiconductor device package of claim 2, wherein:
at least a portion of the first power substrate is at least partially exposed through a major side of the housing; and
at least a portion the second power substrate is at least partially exposed through the major side of the housing.

4. The power semiconductor device package of claim 1, wherein the first submount is a first lead frame and the second submount is a second lead frame.

5. The power semiconductor device package of claim 4, wherein:
at least a portion of the first lead frame is at least partially exposed through a major side of the housing; and
at least a portion of the second lead frame is at least partially exposed through the major side of the housing.

6. The power semiconductor device package of claim 4, wherein:
the first lead frame is on a first power substrate, the first power substrate comprising a plurality of metal layers and an insulating layer between the metal layers; and
the second lead frame is on a second power substrate, the second power substrate comprising a plurality of metal layers and an insulating layer between the metal layers.

7. The power semiconductor device package of claim 6, wherein:
at least a portion of the first power substrate is at least partially exposed through a major side of the housing; and
at least a portion of the second power substrate is at least partially exposed through the major side of the housing.

8. The power semiconductor device package of claim 1, further comprising:
a first plurality of electrical leads coupled to the first semiconductor die and extending from the housing; and
a second plurality of electrical leads coupled to the second semiconductor die and extending from the housing.

9. The power semiconductor device package of claim 8, wherein:
the first plurality of electrical leads comprises a first lead, a second lead, and a third lead; and
the second plurality of electrical leads comprises a first lead, a second lead, and a third lead.

10. The power semiconductor device package of claim 9, wherein the first lead and the second lead of the first plurality of electrical leads extend from an opposing side of the housing relative to the first lead and the second lead of the second plurality of electrical leads.

11. The power semiconductor device package of claim 9, wherein:
for the first plurality of electrical leads:
the first lead and the second lead extend from a first minor side of the housing; and
the third lead extends from a second minor side of the housing that is opposite the first minor side; and
for the second plurality of electrical leads:
the first lead and the second lead extend from the second minor side of the housing; and
the third lead extends from the first minor side of the housing.

12. The power semiconductor device package of claim 11, wherein the creepage extension structure comprises a first creepage portion, a second creepage portion, and a third creepage portion, and wherein:
the first creepage portion is between the first semiconductor die and the second semiconductor die;
the second creepage portion is perpendicular to the first creepage portion and extends laterally between the first creepage portion and a first peripheral end of the housing; and
the third creepage portion is perpendicular to the first creepage portion and extends laterally between the first creepage portion and a second peripheral end of the housing opposite the first peripheral end.

13. The power semiconductor device package of claim 1, wherein the housing comprises a first major side and a second major side opposite the first major side, and wherein:
the first submount comprises a first conductive structure; and
the second submount comprises a second conductive structure.

14. The power semiconductor device package of claim 13, wherein the first conductive structure and the second conductive structure are at least partially exposed through the first major side of the housing.

15. The power semiconductor device package of claim 13, wherein the first conductive structure and the second conductive structure are at least partially exposed through the second major side of the housing.

16. The power semiconductor device package of claim 1, wherein the creepage extension structure is a first creepage extension structure, and wherein the power semiconductor device package further comprises a second creepage extension structure in the housing, the second creepage extension structure on a major side of the housing opposite the first creepage extension structure.

17. The power semiconductor device package of claim 16, further comprising a third creepage extension structure in the housing, the third creepage extension structure on a same major side of the housing as the second creepage extension structure.

18. The power semiconductor device package of claim 1, wherein the creepage extension structure is a first creepage extension structure, the power semiconductor device package further comprising:
a third semiconductor die on a third submount; and
a second creepage extension structure in the housing between the second semiconductor die and the third semiconductor die.

19. A power semiconductor device package, comprising:
a housing;
a first semiconductor die on a first submount; and
a second semiconductor die on a second submount that is electrically isolated from the first submount.

20. A method, comprising:
providing a first submount and a second submount;
coupling a first semiconductor die to the first submount;
coupling a second semiconductor die to the second submount;
providing an encapsulating material around the first submount and the second submount, the encapsulating material forming a housing; and
providing a creepage extension structure in the housing between the first semiconductor die and the second semiconductor die.
